(19) United States
(12) Patent Application Publication
(10) Pub. No.: US 2016/0181969 A1
(43) Pub. Date: Jun. 23, 2016

(54) Photovoltaic Power Farm Structure and Installation

(71) Applicants: Daniel Luch, Morgan Hill, CA (US); Daniel Randolph Luch, Carmel, CA (US)

(72) Inventors: Daniel Luch, Morgan Hill, CA (US); Daniel Randolph Luch, Carmel, CA (US)

(21) Appl. No.: 14/545,454

(22) Filed: May 5, 2015

Related U.S. Application Data
(63) Continuation-in-part of application No. 12/590,222, filed on Nov. 3, 2009, now abandoned.
Application No. 12/590,222 is a continuation-in-part of application No. 12/156,505, filed on Jun. 2, 2008, now abandoned.

(51) Int. Cl. H02S 20/30; H01L 31/05

(52) U.S. Cl. CPC H02S 20/30; H01L 31/0504

(57) ABSTRACT

Unique mounting structures and installation methods for arrays of photovoltaic modules are disclosed. These structures and methods allow for simple, inexpensive and facile production of expansive area solar energy collection facilities. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### CROSS REFERENCE TO RELATED APPLICATION

This application is a Continuation-in-Part of U.S. patent application Ser. No. 12/590,222, filed Nov. 3, 2009 entitled Photovoltaic Power Farm Structure and Installation, which is a Continuation-in-Part of U.S. patent application Ser. No. 12/156,505, filed Jun. 2, 2008, entitled Photovoltaic Power Farm Structure and Installation, now abandoned. The instant application claims the benefit of priority from all of the above identified applications.

### BACKGROUND OF THE INVENTION

Photovoltaic cells convert electromagnetic radiation into electrical power. The individual cell produces power which is directed to cell electrodes of opposite polarity. Electrical connections to these electrodes allow harvesting of the photovoltaically generated power.

Photovoltaic power technology relies heavily on material physics and fabrication processes which dictate the characteristics and type of cell. A first cell type is based on the use of single crystal or polycrystal silicon. The basic cell structure here is defined by the processes available for producing crystalline silicon wafers. The basic form of the wafers is typically a rectangle (such as approximately 6 in.×6 in.) having a thickness of about 0.008 inch. Appropriate doping and heat treating produces individual cells having similar dimensions (6 in.×6 in.). A second cell type is typically referred to as a “thin film”. As the name implies, in the “thin film” cell the photoactive material is deposited as a thin film on a supporting substrate. A third cell type is based on photoactive organic dyes typically deposited in layers on as supporting substrate.

Photovoltaic cells harvest power that is, unless otherwise concentrated by mirrors, etc, relatively diffuse. Thus, bulk power is captured over an extensive collection surface area. Individual cells can be characterized as “high current/low voltage” devices. Thus it is common practice to interconnect multiple cells in series to multiply voltage rather than current so that “IR” losses are minimized during power collection. Serial connections among cells may be made by individually connecting an electrode a first cell with the opposite polarity electrode of a second cell. A number of ways may be used to achieve such connections. One such approach is commonly referred to as “string and tab”, wherein a conductor (tab) between an electrode of one cell and an opposite polarity electrode of another cell. Repeating this arrangement among multiple cells results in a series connected “string” of cells.

Eventually, one or more strings of interconnected cells are positioned and packaged into an assembly commonly referred to as a module. Typical dimensions for such modules may be 3.5 ft.×5 ft. Flexible electrical leads in the form of wires or ribbons of opposite polarity normally extend from the module. These opposite polarity leads often exit the module through a junction box before connections are made to a remote load or to leads from an additional module. Thus, a module can be thought of as a self contained power generator.

The material and manufacturing costs of the crystalline silicon modules are relatively high. In addition, the practical size of the individual module is restricted by weight and batch manufacturing techniques employed. Nevertheless, the crystal silicon photovoltaic modules are quite suitable for small scale applications such as residential roof top applications and off-grid remote power installations. In these applications the crystal silicon cells have relatively high conversion efficiency and proven long term reliability and their restricted form factor has not been an overriding problem. A typical installation involves combining individual modules with additional installation structure and interconnecting using flexible leads or cabling from the individual module junction boxes. Installation structure typically comprises components to support the photovoltaic modules and to secure them in desired positional arrangement. For example, ground mount installations may include racking to support individual modules in desired position. Rooftop installation may employ hardware to secure modules to a roof. Photovoltaic installations may often be characterized as “custom designed” for the specific site, requiring significant site preparation prior to module installation. This further increases cost. Cost, weight and size restrictions may act as deterrents for use of crystalline photovoltaic cells for many bulk power generation efforts.

A second approach to photovoltaic cell manufacture comprises the so-called thin film structure. Here thin films (thickness of the order of microns) of appropriate semiconductors are deposited on a supporting substrate or superstrate. Thin films may be deposited over expansive areas. Indeed, many of the manufacturing techniques for thin film photovoltaic cells take advantage of this ability, employing relatively large glass substrates or continuous processing such as roll-to-roll manufacture using flexible continuous substrates. However, many thin films require heat treatments which are destructive of even the most temperature resistant polymers. Thus, thin films such as CIGS, CdTe and a-silicon are often deposited on glass or a metal foil such as stainless steel or aluminum.

Deposition of thin films on glass surfaces restricts the ultimate module size and typically involves output in batch form. In addition deposition on glass normally forces expensive and delicate material removal processing such as laser scribing to subdivide the expansive surface into individual interconnected cells remaining on the original glass substrate (often referred to as monolithic integration). Finally, it is difficult to incorporate collector electrodes over the top light incident surface of cells when employing glass superstrates. This often forces cell widths to be relatively small, typically about 0.5 cm. to 1.0 cm. Series interconnecting the large number of resulting individual cells may result in large voltages for a particular module which may be hazardous and require additional expense to insure against electrical shock.

Deposition of thin film semiconductors on a metal foil such as stainless steel or aluminum can be accomplished continuously over expansive surfaces. However, because the substrate is conductive, monolithic integration techniques used for nonconductive substrates may involve additional complication. Thus, integration approaches for metal foil substrates generally envision subdivision into individual cells which can be subsequently interconnected. However handling, repositioning and integration of the multiple individual cells has proven troublesome. One technique is to use the “string and tab” approach developed for crystalline silicon cells referred to above. Such an approach reduces the ultimate value of continuous thin film production by introducing a tedious, expensive batch “back end” assembly process. Many cost and size limitations associated with crystal silicon technology are still present when using “string and tab” interconnections with thin film cells.

There remains a need for improved interconnection and packaging technology for photovoltaic devices. This need is particularly evident when considering bulk power applications.

Unique improved technology for interconnecting and packaging photovoltaic cells is taught by Luch in a number of U.S. patents. Luch taught the manufacture of modules using unique technology for mechanically and electrically interconnecting multiple cells. Luch's teachings were applicable to a wide variety of photovoltaic cell types, including crystal silicon and thin film cells. The completed Luch modular structures can be quite expansive (i.e. 2 ft. by 8 ft., 4 ft. by 8 ft., 8 ft. by 20 ft., 8 ft. by continuous length etc.). Thus Luch taught modules having low cost and optionally large form factors. A sampling of the Luch photovoltaic patents are U.S. Pat. No. 8,076,568, U.S. Pat. No. 8,117,737, U.S. Pat. No. 8,138,413, U.S. Pat. No. 8,222,513, and U.S. Pat. No. 8,822,810.

Photovoltaic power technology has been applied to multiple, highly diverse applications. For example, small portable handheld devices such as calculators may employ photovoltaic collection surface areas on the order of square inches. Outer space power generation may employ significantly larger collection surface areas. Significant efforts have also focused on terrestrial bulk power generation. Terrestrial bulk power applications include expansive ground based installations and more distributed applications such as those on commercial and residential rooftops. In these terrestrial bulk power applications, a significant cost of the installation involves the “balance of system” costs associated with site preparation, construction of installation structures, module placement and power management. For example, expansive ground mount installations normally involve construction of concrete embedded support racks for the modules. For rooftop applications, often module support racks are attached to the roof with roof penetrating hardware. Therefore, in most cases involving terrestrial bulk power capture, modules having collection surface areas larger than about four square foot are employed to reduce “balance of system” costs. The modules are typically constructed and shipped the installation site as individual units where they are combined with installation structure to complete the installation.

Alternate proposals have been made to incorporate small individual “modules” into shingles for residential rooftop applications. These photovoltaic “shingles” are designed and sized to visually resemble typical roof shingles (i.e. about 1 square foot or less of collection surface of series connected cells per shingle). Economic considerations generally dictate larger collection areas for modules, normally greater than 1 square foot (i.e. 2 sq. ft., 4 sq. ft., 8 sq. ft., 12 sq. ft., 20 sq. ft., 32 sq ft.). Cost along with other factors have to date thwarted widespread acceptance of the “shingle” approach.

An additional consideration with photovoltaic applications is power conditioning of the photovoltaic power. The voltage and current components of photovoltaic power can be variable over time. In order to be most broadly useful, this power is usually modified to constant, defined characteristics. In a simple application, this conditioning can be done by simply charging one or more batteries. In other cases, particularly residential applications, additional complications such as shading and large power variations have led to the introduction of power conditioning devices on individual modules. These devices serve to condition the input power from individual modules such that the output is predictable and suitable for the intended application. Such electronic modification at the module level supplies significant improvements associated with the unique problems of residential rooftop applications.

The function of a power conditioning device may vary. Some devices are intended to change the direct current power from a photovoltaic module and produce alternating current at a specific voltage. Other approaches envision boosting a variable output voltage from modules to a constant predetermined increased voltage. In this latter example, multiple modules may be combined in parallel at the elevated voltage to reduce resistance losses in downstream power transport.

Power conditioning of individual module output may significantly increase the “cost per watt” of the collected power. Packaging of the electronics associated with the power conditioning is responsible for a significant portion of the cost of the conditioning equipment. Due to the added cost and differing challenges, power modification at the module level has not been widely adopted for more expansive commercial applications such as ground mount or commercial rooftops installations. There, power conditioning is typically accomplished with an inverter receiving power from an array of a large number of modules. However, this approach also has characteristic drawbacks in that deficient performance of one module may adversely affect other modules in an array.

A further issue that has impeded adoption of photovoltaic technology for bulk power collection in the form of solar farms involves installation of multiple modules over expansive regions of surface. Traditionally, multiple individual modules have been mounted on racks, normally at an incline to horizontal appropriate to the latitude of the site. Flexible conducting leads or cabling from each module are then physically coupled with similar flexible leads from an adjacent module in order to interconnect multiple modules. This arrangement results in a string of modules each of which is coupled to an adjacent module. At one end of the string, the power is transferred from the end module and conveyed to a separate site for further power conditioning such as voltage adjustment. This arrangement avoids having to run conductive cabling from each individual module to the separate conditioning site.

The traditional solar farm installation described in the above paragraph has some drawbacks. First, the module itself comprises one or more strings of individual cells. In the conventional module conductors in the form of flexible wires or ribbons are attached to an electrode on the two cells positioned at each end of the string in order to convey the power from the string to a central junction box of the module. One problem is that the attachment of conductors to the cell strings is often a manual operation requiring tedious operations such as soldering. Next, unwieldy flexible conductive leads from the module must be directed and secured in position, again a tedious operation. Finally, after mounting the module on its support at the installation site, the respective leads from adjacent modules must be connected in order to couple adjacent modules, and the connection must be protected to avoid environmental deterioration or separation. These are typically tedious manual operations. Finally, since the module leads and cell interconnections are not of high current carrying capacity, the adjacent cells are normally connected in series arrangement. Thus voltage builds up to high levels even with a relatively small number of interconnected modules. Thus, skilled labor having electrical awareness is normally required for bulk installation. Finally, security and insulation must be appropriate to eliminate a shock hazard while in operation. There remains a need for improved collection and conveyance of power from an aggregate large number of individual photovoltaic modules

There remains a need for structure and methods allowing inexpensive installation of photovoltaic modules over large surface areas such as terrestrial surfaces and large commercial and possibly residential building rooftops.

In order to promote clarity and complete understanding of the instant teachings and claims, the following definitions and explanations are supplied.

While not precisely definable, electrically insulating materials may generally be characterized as having electrical resistivities greater than about 10,000 ohm-cm. Also, electrically conductive materials may generally be defined and characterized as materials having electrical resistivities less than 0.001 ohm-cm. Also electrically resistive or semi-conductive materials may generally be characterized as having electrical resistivities in the range of 0.001 ohm-cm to 10,000 ohm-cm., although such materials are also often characterized as simply “conductive”. For example, certain metal oxides are characterized as “conductive” even though they may have resistivities greater than 0.001 ohm-cm. Also, the characterization “electrically conductive polymer” covers a very wide range of intrinsic resistivities depending on the application, the filler, the filler loading and the methods of manufacture of the filler/polymer blend. Resistivities for electrically conductive polymers may be as low as 0.00001 ohm-cm. for very heavily filled silver inks, yet may be as high as 10,000 ohm-cm or even more for lightly filled carbon black materials or other “anti-static” materials. “Electrically conductive polymer” has become a broad industry term to characterize all such materials. Thus, the term “electrically conductive polymer” as used in the art and in this specification and claims extends to materials of a very wide range of resitivities from about 0.00001 ohm-cm. to about 10,000 ohm-cm and higher.

“Substantially” means being largely or wholly that which is specified.

“Essentially” means fundamentally or “for all intents and purposes”.

A “pattern” is a design or arrangement.

“Direct physical contact” means “touching”.

A “low melting point” metal or alloy is one with a melting point less than 600 degrees Fahrenheit.

“Selectively positioned” means that which is specified is positioned in a preselected arrangement or design.

“Terminal edge” is a boundary outside of which there is none of that which is specified.

An “electroplateable material” is a material having suitable attributes that allow it to be coated with a layer of electrodeposited material, either directly or following a preplating process.

A “metallizable material” is a material suitable to be coated with a metal deposited by any one or more of the available metallizing processes, including but not limited to chemical deposition, vacuum metallizing, sputtering, metal spraying, sintering electroless deposition and electrodeposition.

“Metal-based” refers to a material or structure having at least one metallic property and comprising one or more components at least one of which is a metal or metal-containing alloy.

“Alloy” refers to a substance composed of two or more intimately mixed materials.

“Group VIII metal-based” refers to a substance containing by weight 50% to 100% metal from Group VIII of the Periodic Table of Elements.

A “metal-based foil”, “bulk metal foil”, “bulk metal wire” etc. refers to structure of metal or metal-based material that may maintain its integrity absent a supporting structure. Generally, metal films of thickness greater than about 2 micrometers may have this characteristic (i.e. 2 micrometers, 10 micrometers, 25 micrometers, 100 micrometers, 250 micrometers etc.). Thus, in most cases a “bulk metal foil” will have a thickness between about 2 micrometers and 250 micrometers and may comprise a structure of multiple layers. Metal wires of diameter greater than about 10 micrometers may exhibit self supporting characteristic and therefore be classified as a “bulk metal wire” wire form.

A “self supporting” structure is one that can be expected to substantially maintain its integrity and form absent supporting structure.

“Portion” means a part of a whole item. When used herein, “portion” may indicate 100 percent or less of the whole item (i.e. 100 percent, 90 percent, 80 percent, 70 percent, 60 percent, 50 percent, 40 percent, 30 percent, 20 percent, 10 percent 5 percent, and 1 percent).

A “film” refers to a thin material form having length and width much greater than its thickness that may or may not be self supporting.

The terms “monolithic” or “monolithic structure” are used as is common in industry to describe structure that is made or formed from a single or uniform material. An example would be a “boat having a monolithic plastic hull”.

A “continuous form” of material is one that has a length dimension far greater than its width or thickness such that the material can be supplied or produced in its length dimension without substantial interruption.

A “continuous process” is one wherein a continuous form of a material component is supplied to or produced by the process. The material feed or output can be as continuous motion or repetitively intermittent. The output product is normally removed either by continuous motion or repetitively intermittent according to the rate of input.

A “roll-to-roll” process is one wherein a material component is fed to the process from a roll of material and the output of the process is accumulated in a roll form.

The “machine direction” is that direction in which material is transported through a process step.

The term “multiple” is used herein to mean “two or more”.

“Sheetlike” characterizes a structure or form having surface dimensions far greater than a thickness dimension. A “sheetlike” structure or form can comprise multiple layers and has a top side (defined by length and width) and an oppositely disposed bottom side.

A “web” is a sheetlike material form often characterized as continuous in a length direction.

An “adhesive” is a material that can bond to a surface or object.

A “laminating adhesive” is an adhesive material in the form of a layer or film. The adhesive will typically be activated using heat or pressure or a combination of both.

“Adhesive affinity” is a characteristic of a material's ability to adhesively bond to a mating surface. A material has “adhesive affinity” for a mating surface if it can form or has formed an adhesive bond directly to that surface using appropriate adhesive processing.

“Substantially planar” or “essentially planar characterize a surface structure which may comprise minor variations in surface topography but from an overall and functional perspective can be considered essentially flat.

The terms “upper”, “upward facing”, and “top” surfaces or sides of structure refer to those surfaces or sides of structures facing upward in normal use. For example, when used to describe a photovoltaic device, an “upper” surface or side refers to that surface or side intended to face the sun.

The terms “lower”, “downward facing” or “bottom” surfaces or sides refer to surfaces or sides facing away from an upper, upward facing or top surface or side of the structure.

The term “polymer” refers to materials comprising repetitive structural units. Polymers are often commonly referred to as “plastics”. Polymers comprise a broad class of materials having a wide variety of chemical, physical and mechanical properties. Most common polymers are carbon based (organic polymers) or silicon based (for example silicone materials).

“Polymeric” refers to a material or structure comprising a polymer.

“Organic” materials are those based on or having a significant portion of their structure and characteristics defined by carbon. “Inorganic” materials are those substantially absent carbon.

The term “cross-linked” indicates a polymer condition wherein bonding occurs between polymer chains. Prior to “cross-linking”, a polymer may be “flowable” under temperature and pressure. After “cross-linking” the polymer resists flow.

A “thermoplastic” material is one that becomes fluid and can flow at an elevated temperature. A thermoplastic material may be relatively rigid and non-tacky at room temperature and becomes fluid at elevated temperature above ambient.

An “ohmic” connection, joining or communication is one that behaves electrically in a manner substantially in accordance with Ohm's Law.

“Conductive joining” refers to fastening two conductive articles together such that ohmic electrical communication is achieved between them. “Conductive joining” includes soldering, welding such as achieved with current, laser, heat etc., conductive adhesive application, mechanical contacts achieved with crimping, twisting and the like, and laminated contacts.

An “additive process” is one wherein there is no substantial removal of material in order to generate a desired material form. Examples of additive processing are metal electrodeposition and placement of preformed shapes such as metal wires and strips. An example of non-additive processing (subtractive processing) is photoetching of metal foils to produce selectively patterned metal devices.

A “structural polymer” is a polymer, such as a plastic, that can provide structural support, often to overlying or underlying structure. A “structural polymer” may function as a “polymeric support” or a “polymeric carrier”.

“Heat sealing” is a process of attaching two forms together using heat. Heat sealing normally involves softening of the surfaces of one or both forms to allow material flow and bond activation. “Heat sealing” can involve a simple welding of two similar materials or may employ an intermediary adhesive to bond (seal) the two materials to each other.

“Overlapping” identifies a condition wherein one layer or structure either completely or partially overlays or covers another. Overlapping may comprise either complete or partial coverage.

“Laminating” is a process involving the mating of two or more surfaces. It normally involves partial or complete overlapping of two or more material bodies. The bodies normally have a “sheetlike” form such that the laminating process positions the “sheetlike” forms relative to each other as a layered combination. Laminating often involves the activation of an intermediary “laminating” adhesive medium between the“sheetlike” forms to securely attach the layers to each other. Activation of the “laminating” adhesive is normally accomplished using heat and/or pressure to cause the adhesive to soften and flow to “wet” and intimately contact the mating surface.

“Vacuum lamination” is a process wherein multiple material layers are stacked and a vacuum is drawn encompassing the assembly. Heat is also normally used to activate intermediary adhesive layers to bond the stacked layers together.

“Roll lamination” is a process wherein one or more material layers are fed to a pair of rollers positioned with a determined separation (a “nip”). In passing through the “nip” the layers are squeezed together. The layers may be heated during the squeezing process to cause flow and contact of an intermediary thermoplastic adhesive. Alternatively, a pressure sensitive adhesive may be employed without heating wherein pressure causes flow of adhesive to wet the surfaces.

A “laminated contact” is an electrical and physical contact between two conductive structures which is established and maintained by a polymeric laminating adhesive. A first of the conductive structures is positioned between the polymeric adhesive and a surface of the second conductive structure. Laminating the adhesive to the surface of the second structure keeps the first conductive structure between them. The “blanketing” of the first conductive structure securely holds the first and second conductive structures together.

When describing an object, the adjective “flexible” means that the object may be significantly deformed without breaking. An object may often be flexible because one of its dimensions such as thickness is small. In addition, flexibility is often, though not always, accompanied by elasticity in that the object is not necessarily permanently deformed by bending and can be returned to substantially its original shape after being deformed.

The terms “preponderance” or “major portion” designate a quantity greater than fifty percent (i.e. 50%, 60%, 70%, 80%, 90%, 95%, 100%).

“Transparent” is an adjective characterizing a material or structure that will transmit a preponderance or major portion of impinging light or electromagnetic radiation. When used to characterize a component of a photovoltaic device, transparent describes structure which transmits radiation (such as visible light) to an extent sufficient to allow acceptable performance of the device.

“Translucent” is an adjective characterizing a structure that transmits a preponderance or major portion of impinging light or electromagnetic radiation but diffuses a portion such that transmitted images are rendered somewhat cloudy or blurred.

“Metal oxide” is a chemical compound comprising two or more elements one of which is oxygen and at least one of which is a metal.

“Substrate” is a structure that can provide support.

An “interconnection component” or “interconnecting component” is a structure designed to facilitate power collection from one or more photovoltaic cells. An “interconnection component” may comprise a current collector structure, an interconnection structure, or a combination of both a current collector and interconnection structure.

“Solder” is a low melting point metal or metal alloy often used to achieve conductive joining.

“Conductive adhesive” is a conductive polymeric material that can adhesively bond to a surface. “Conductive adhesives” are often employed to achieve conductive joining.

A “coating” is a layer of material overlaying a base structure.

“Integral” means “forming an essential part of something”.

“Portable” means “readily transported or moveable”.

“Non-Portable” means “that which is specified is not readily moved as an aggregate or assembly”. An example is a building that when completed is “non-portable” but whose components (wood, nails, electrical items etc.) are portable prior to assembly.

“Polarity” refers to the condition in a system of having opposite characteristics at different points, especially with respect to electric charge or magnetic properties.

“Bulk power” is power intended for distribution to more than one device or location.

“Stationary” means immobile or “staying in the same place”.

A “rail” is a long or extended piece of material.

A photovoltaic “module” comprises one or more electrically interconnected photovoltaic cells. Typically a “module” will comprise multiple cells.

“Power conditioning” is altering a stream of input power to output power having predefined characteristics.

“Installation structure” refers to components in addition to the photovoltaic modules employed to complete a photovoltaic installation.

An “installation unit” comprises a combination of one or more modules and installation structure.

“Inseparable” means not intended or designed to be separated or parted.

### OBJECTS OF THE INVENTION

An object of the invention is to teach structure and methods allowing improved installation of photovoltaic modules over expansive surface areas.

A further object of the invention is to teach methods to reduce cost and complexity of photovoltaic power installations.

### SUMMARY OF THE INVENTION

The invention teaches structure and methodology to improve application of photovoltaic modules. The invention may employ large form factors of photovoltaic modules such as those contemplated in the aforementioned U.S. patents of Luch. However, other forms of photovoltaic modules (for example those employing crystal silicon cells) may also be employed.

In one embodiment, the teachings of the above-referenced Luch patents are used to produce modules having a “sheetlike” form. The “sheetlike” form may be flexible. The modules may have relatively large dimensions. Specifically, practical module widths may be 2 ft., 4 ft., 8 ft., 16 ft., etc. Practical module lengths may be 2 ft., 4 ft., 10 ft., 50 ft, 100 ft., 500 ft., etc. The longer lengths can be characterized as “continuous” and be shipped and installed in a roll format.

In an embodiment a module comprises a sheet of transparent material supplying environmental protection applied prior to installing the modules onto an installation structure.

In an embodiment a module comprises a sealing gasket positioned outside a surface area defined by active photovoltaic semiconductor material.

In an embodiment a desiccant is positioned within a perimeter defined by a sealing gasket.

In an embodiment module manufacture comprises roll lamination of a flexible arrangement of multiple interconnected cells to a glass sheet.

In an embodiment a module may comprise thin film photovoltaic cells.

In an embodiment the photovoltaic cells comprise thin film semiconductor material supported on a metal foil.

In an embodiment, individual modules are absent junction boxes.

In an embodiment a module is absent flexible, unwieldy conductive wire or ribbon leads extending from the module surface.

In an embodiment a module comprises terminal bars of opposite polarity.

In an embodiment a module comprises terminal bars of opposite polarity having a conductive surface at least partially positioned outside a boundary of an overlaying transparent protective layer.

In an embodiment a module comprises a terminal bar having monolithic structure common with a current collector structure of an end cell of the module.

In an embodiment terminal bars extend over substantially the entire width of the module.

In an embodiment individual cells extend substantially the entire width of a module and the terminal bars are positioned at opposite ends of the module length dimension.

In an embodiment current flows in a single direction throughout the arrangement of cells.

In an embodiment terminal bars provide an upward facing conductive surface.

In an embodiment a terminal bar has oppositely facing conductive surface portions in electrical communication.

In an embodiment a terminal bar has oppositely facing conductive surface portions in electrical communication and separated by an insulator.

In an embodiment module terminal bars have structure to facilitate attachment to installation structure.

In an embodiment a module terminal bar has attachment structure comprising holes extending through a module terminal bar.

In an embodiment holes extending through a module terminal bar are complimentary to structure present on installation structure.

In an embodiment cells extend over substantially the entire width of a module and the cells are connected in series such that voltage increases progressively in the length dimension of the module while remaining constant over the module width dimension.

In an embodiment an installation structure comprises a mesh structure to assist supporting a large area module.

In an embodiment an installation structure comprises a ballast material intended to supply stabilizing weight to the structure.

In an embodiment a ballast material of the installation structure comprises water.

In an embodiment a ballast material of the installation structure comprises concrete.

In an embodiment the installation structure comprises one or more water filled tanks.

In an embodiment an installation structure supports a module above a base surface with a space between the module and base surface.

In an embodiment, an installation structure comprises receiving structure to receive and position a photovoltaic module.

In an embodiment a portable installation structure comprises structure to facilitate transport and placement.

In an embodiment a portable installation structure comprises structure to cooperate with the forks of forklift equipment to facilitate transport and placement.

In an embodiment, power conditioning equipment is included as an integral part of the installation structure.

In an embodiment, a rail conducting photovoltaically generated power is an integral component of the installation structure.

In an embodiment, conductors for power conveyance are incorporated as an integral part of the installation structure.

In an embodiment, an installation structure comprises a sloped surface to support a module at an angle to the horizontal.

In an embodiment, an installation structure comprises a hinge such that the mounted modules may be angled relative to the horizontal.

In an embodiment, an installation structure comprises a plastic living hinge such that the mounted modules may be angled relative to the horizontal.

In an embodiment, installation structure serves as a major support for one or more modules.

In an embodiment installation structure comprises integral conductive material electrically joining multiple modules.

In an embodiment installation structure may also serve to position conductive rails for conveying the power from multiple units.

In an embodiment, an installation unit comprises a combination of one or more modules and installation structure.

In an embodiment the installed modules are supplied with environmental protection by applying sheets of transparent material after the one or more modules have been installed onto installation structure.

In an embodiment, electrical connection among adjacent modules is accomplished absent flexible electrical leads extending from the modules.

In one embodiment a module may be removed from the installation structure simply and readily replaced with another module.

In an embodiment a fastener connecting a module to installation structure is a mechanical fastener.

In an embodiment a module is attached to installation structure using a conductive mechanical fastener which also functions to conduct photovoltaically generated power.

In an embodiment a fastener connecting a module to installation structure is characterized as rigid.

In an embodiment a fastener connecting a module to installation structure comprises screw threads.

In an embodiment a fastener connecting a module to installation structure utilizes snap attachment.

In an embodiment a fastener connecting a module to installation structure comprises a plug.

In an embodiment a fastener connecting a module to installation structure is electrically conductive.

In an embodiment a fastener is a threaded bolt, and expansion bolt, a metal anchor, a plug, a rivet or U-bolt.

In an embodiment a conducting fastener serves to secure a module to a conductive installation structure and also convey photovoltaically generated current away from said module to the conductive installation structure.

In an embodiment a rigid electrical connection is made between a module terminal bar and a conductive installation structure.

In an embodiment one or more modules are mounted on a transportable pallet-like installation structure comprising a molded tank. The tank may be filled with liquid to supply both weight and thermal ballast.

In an embodiment a portion of the installation structure may be adjusted to alter the tilt of the module relative to horizontal.

In an embodiment, sheetlike modules are adhered to rigid installation structure such as a piece of glass, plywood, polymeric sheet, wire mesh or a honeycomb structure.

In an embodiment installation structure comprises plastic.

In an embodiment, an installation structure is absent ground or roof penetrating anchors.

In an embodiment, one or more modules are mounted on an installation structure and the installation structure includes a power modification or conditioning device.

In an embodiment, a first installation unit comprises interlocking structure complimentary to interlocking structure on a second installation unit such that the complimentary interlocking structures maintain the two units in adjacent positioning

In an embodiment, interlocking structure on first and second installation units serves to ohmically join conductive material associated with the units.

In one embodiment, one or more modules are assembled on a common installation structure and are electrically connected to produce a common voltage and wherein the power generated by the assembly of modules is fed to a power conditioning device designed as an integral component of the installation structure.

In one embodiment, each module or assembly of modules has its output modified by power conditioning which is built into the installation structure.

In an embodiment, an installation unit is constructed absent junction boxes and unwieldy flexible leads extending from the individual photovoltaic modules.

In an embodiment, complimentary male plug/female receptacle connections are used to establish electrical communication between photovoltaic modules and electrical components integral with the installation structure.

In an embodiment, multiple installation units have complimentary structure to facilitate placement and positioning of one unit adjacent another.

In an embodiment, complimentary structure facilitating positioning of adjacent installation units comprises a snap fitting.

In an embodiment, complimentary structure facilitating positioning of adjacent installation units comprises an electrical connector.

In an embodiment, complimentary male/female plugs constituting integral components of installation structures electrically connect adjacent installation units.

In an embodiment, multiple installation units are repetitively positioned adjacent each other.

In an embodiment a rail extends to attach to multiple units to mechanically secure the units together.

In an embodiment a rail extends to electrically join multiple units together to convey photovoltaically generated power from the multiple units.

In an embodiment multiple units, each comprising transportable pallet-like structure, are arranged adjacent each other and connected by current carrying rails.

In an embodiment multiple individual modules form series connected portions of a larger deployment and multiple series connected portions are interconnected in parallel.

In an embodiment a rail is increased in cross section along its length to accommodate increasing current.

In an embodiment an installation structure comprises elongate rails which may comprise metal having high current carrying capacity such as aluminum or copper.

In an embodiment a rail serves as a common electrical manifold or buss to convey power from multiple modules.

In an embodiment a rail serves as a common electrical manifold or buss to convey power from multiple installation units.

In an embodiment a rail contributes to conveying current in forming a series connection between adjacent modules.

In an embodiment a rail contributes to conveying current in forming a parallel connection between adjacent modules.

In an embodiment a rail contributes to conveying current in forming a parallel connection between adjacent installation units.

In an embodiment a rail contributes to conveying current in forming a series connection between adjacent installation units.

In an embodiment, a photovoltaic installation is absent unwieldy flexible lead wires extending from individual modules.

In an embodiment, complimentary electrical connectors are used to create a bus for electrical communication among multiple installation units.

In an embodiment, complimentary male plug/female receptacle connections are used to establish electrical communication between adjacent installation units.

In an embodiment, elongate rails extend among multiple installation units to secure multiple installation units together.

In an embodiment, elongate rails extending among multiple installation units convey photovoltaically generated power.

In an embodiment, adjacent installation units are electrically connected absent flexible connectors.

In an embodiment, adjacent installation units are electrically connected using flexible connectors or “jumpers”.

In an embodiment, a photovoltaic installation comprises multiple installation units which are absent ground or roof penetrating structure.

In an embodiment, installation units are mounted directly on power conveying rails.

In one an embodiment power conveying rails contribute to a frame designed for conveniently receiving a module or unit of predetermined geometry.

In an embodiment a flexible module is attached directly to a roof and rails are attached to collect current from the modules.

In one embodiment power is conveyed from individual modules at a voltage characterized as non-hazardous.

In one embodiment power is conveyed from individual modules at a voltage less than 50 volts.

In an embodiment installation structure suitable for supporting one or more photovoltaic modules is substantially wholly constructed at the installation site prior to installation of the photovoltaic modules.

In an embodiment an installation structure suitable for supporting one or more photovoltaic modules is constructed at a manufacturing site remote from the installation site.

In an embodiment a portable installation structure is constructed prior to transport to the installation site.

In an embodiment a module is mounted on a transportable installation structure prior to transport to an installation site.

In an embodiment, an installation unit combining one or more modules and an installation structure is assembled prior to transport to an installation site.

In an embodiment installation structure suitable for receiving a module of extended length is constructed. An extended length module is shipped to the site and the module is combined with the installation structure by simply applying the module onto the installation structure. Power output connections are made at each end of the extended length module.

### BRIEF DESCRIPTION OF THE DRAWINGS

The various factors and details of the structures and manufacturing methods of the present invention are hereinafter more fully set forth with reference to the accompanying drawings wherein:

FIG. 1 is a top plan view of a portion of a modular structure comprising interconnected photovoltaic cells useful for the instant invention.

FIG. 2 is a sectional view taken substantially from the perspective of lines 2-2 of FIG. 1.

FIG. 3 is a simplified overall top plan view of a modular structure comprising interconnected photovoltaic cells useful for the instant invention showing some important features contributing to the invention.

FIG. 4 is a perspective view of the FIG. 3 structure.

FIG. 5 is a sectional view of a portion of a photovoltaic module comprising the interconnected cells of FIG. 3 plus additional functional components. In the FIG. 5 sectional lines have been omitted for clarity.

FIG. 5A is a side view of a possible process by which a portion of the FIG. 5 structure may be manufactured.

FIG. 6 is a top plan view of a simplified embodiment of an installation structure.

FIG. 7 is sectional view taken substantially from the perspective of lines 7-7 of FIG. 6.

FIG. 8 is a perspective view showing the overall arrangement of a simplified embodiment of installation structure prior to installation of photovoltaic modules.

FIG. 9 is a perspective view showing multiple modules (3) installed on the simplified structure of FIGS. 6 through 8.

FIG. 10 is a perspective view exploding the region within circle “10-10” of FIG. 9 and illustrating the details of one form of electrical and structural joining of a module to the installation structure.

FIG. 11 is a view partially in section further illustrating the details of the mounting arrangement shown in the perspective view of FIG. 10.

FIG. 12 is a view similar to FIG. 11 showing additional optional components of the mounted module.

FIG. 13 is a view similar to FIG. 11 showing a alternate means to electrically and mechanically attach a module to an installation structure.

FIG. 14 is a view similar to FIG. 11 showing yet another alternate means to electrically and mechanically attach a module to an installation structure.

FIG. 15 is a perspective view of an installation structure showing additional functional components.

FIG. 16 shows the installation structure of FIG. 15 along with two modules as depicted in FIG. 4.

FIG. 17 is a sectional view depicting an alternate component for installation structure.

FIG. 18 is a top plan view showing an alternate form of installation structure.

FIG. 19 is a side view of the installation structure of FIG. 18.

FIG. 20 is a side view showing the installation structure of FIG. 19 having a module such as depicted in FIG. 5 mounted thereon.

FIG. 21 is a top plan view of multiple modules mounted as shown in FIG. 20 with the multiple modules interconnected in parallel.

FIG. 22 is a side view partially in section taken substantially from the perspective of lines 22-22 of FIG. 21.

FIG. 23 is a side elevational view similar to FIG. 20 but showing an alternate form of installation structure.

FIG. 23A is a side view similar to FIG. 23 showing another embodiment of installation structure.

FIG. 24 is a top plan of another structural embodiment of the novel installations of the instant invention.

FIG. 25 is a perspective view of a portion of the structure depicted in FIG. 24.

FIG. 26 is a top plan view of the installation structure of FIGS. 24-25 with photovoltaic modules mounted thereon.

FIG. 27 is a view partially in section taken substantially from the perspective of lines 27-27 of FIG. 26 following the installation of a photovoltaic module and rigid fasteners.

FIG. 28 is a view similar to FIG. 27 of an alternate fastening structure for mounting multiple modules.

FIG. 29 is a view similar to those of FIGS. 27 and 28 showing yet another fastening structure for mounting multiple modules.

FIG. 30 is a top plan view showing a array of modules employing both series and parallel interconnections.

FIG. 31 is a top plan view of another embodiment of the novel supporting structures of the instant invention.

FIG. 32 is a sectional view taken from the perspective of lines 32-32 of FIG. 31.

FIG. 33 is a view similar to FIG. 32 following an additional installation step.

FIG. 34 is a view similar to FIG. 33 following an application of additional optional materials to the FIG. 33 structure.

FIG. 35 is a side view of an arrangement to maximize radiation impingement on an array of modules.

FIG. 36 is a top plan view of an embodiment of installed photovoltaic structure including photovoltaic modules and installation structure.

FIG. 37 is a frontal side view of a component of the FIG. 36 structure.

FIG. 38 is a sectional view taken from the perspective of lines 38-38 of FIG. 36.

FIG. 39 is a side view of another embodiment of an installation unit comprising photovoltaic modules combined with installation structure.

### DESCRIPTION OF PREFERRED EMBODIMENTS

Reference will now be made in detail to the preferred embodiments of the invention, examples of which are illustrated in the accompanying drawings. In the drawings, like reference numerals designate identical, equivalent or corresponding parts throughout several views and an additional letter designation may indicate a particular embodiment.

Applications of photovoltaic modules produced according to the above-referenced Luch teachings include expansive area photovoltaic energy farms or expansive area rooftop coverage. These applications of the Luch modules, as well as applications of other types of modules, may be facilitated by the teachings of the instant invention.

The modules produced according to the Luch teachings may have terminal bars at opposite terminal ends of a group of interconnected photovoltaic cells. As used herein, a terminal bar is a region of conductive surface electrically connected to an electrode of an end cell of the interconnected cells. A terminal bar supplies an accessible conductive surface to contact and enable power to be collected from the interconnected cells. In this regard, alternate structures producing effectively conductive surface regions may be functionally equivalent to the substantially planar terminal bars embodied in the instant figures. Such equivalents include multiple wires or strips extending from the end cell, conductive meshes, conductive ink patterns and the like. All such equivalents are included by the term “terminal bar” as used herein. As will be seen, incorporation of appropriate terminal bars as an integral part of the module construction allows one to make electrical connections from the terminal bar to exterior conductors without junction boxes or unwieldy flexible metallic wire or ribbon leads emanating from the module.

Returning to the above referenced Luch patents reveals that terminal bars are easily incorporated into the modules using the same processing as is used in assembly of the bulk module. It is noted that in his patents and applications, Luch taught that the terminal bars may have oppositely facing conductive surface regions with electrical communication between them. In preferred embodiments, Luch achieved dual sided electrical communication by chemically or electrochemically plating metal through holes extending through an insulating substrate. This is an advantage for certain embodiments of the instant invention. Another advantage of the embodiments of the above-referenced Luch teachings is that terminal bars and the conductive current collector or electrode structure associated with the end cell can comprise a monolithic component forming portions of both the terminal bar and collector/electrode structure. Here the term “monolithic” or “monolithic structure” is used as is common in industry to describe a structure that is made or formed from a single item or material.

Referring now to FIGS. 1 through 3 of this instant specification, details of a structure appropriate for the invention are embodied. In FIG. 1, a top plan view of photovoltaic modular structure 10 is depicted. The FIG. 1 depiction includes one terminal end 12 of the module. Positioned along the edge of the terminal end 12 is electrically conductive terminal bar 14. One understands that a terminal bar of opposite polarity would be positioned at the terminal end opposite terminal end 12 (not shown in FIG. 1). The terminal bars are normally positioned adjacent or close to an end cell.

In the embodiment of FIG. 1, through holes 16 have been positioned within the terminal bar 14. As will be shown, through holes 16 may be used to achieve both structural mounting and electrical joining to an installation structure. In addition, as is clearly taught in the Luch U.S. patents referenced above, through holes such as those indicated by 16 may be used to achieve electrical communication between conductive surfaces on opposite sides of an insulating substrate in the terminal bar region. This feature expands installation design choices and may improve overall contact between the terminal bars and conductive attachment hardware.

Continuing reference to FIG. 1 shows photovoltaic cells 1, 2, 3, etc. positioned in a repetitive arrangement. In the embodiment, the individual cells comprise thin film semiconductor material supported by a metal-based foil. This structure is more fully discussed in the above-referenced Luch patents. However, the invention is not limited to such structure. Alternate photovoltaic cell structures known in the art and incorporated into expansive modules could be appropriate for practice of the invention. These alternate structures include, but are not limited to (a) thin film cells deposited on polymeric film substrates or superstrates and those interconnected monolithically or by known “shingling” techniques, (b) structures employing single or multi-crystal silicon, (c) structures employing photoactive organic materials, (d) structures employing photoactive layers of inorganic materials.

On the top (light incident) surface 18 of the cells in the FIG. 1 embodiment, a pattern of fingers 20 and busses 22 function as a current collecting electrode for power transport to an adjacent cell in series arrangement. The grid finger/buss collector is but one of a number of means to accomplish power collection and transport among cells. Methods such as conductive through holes from the top surface to a backside electrode, monolithically integrated structures using polymeric or glass substrates or superstrates, known shingling techniques and “string-and tab” interconnections may also be considered in the practice of aspects of the instant invention.

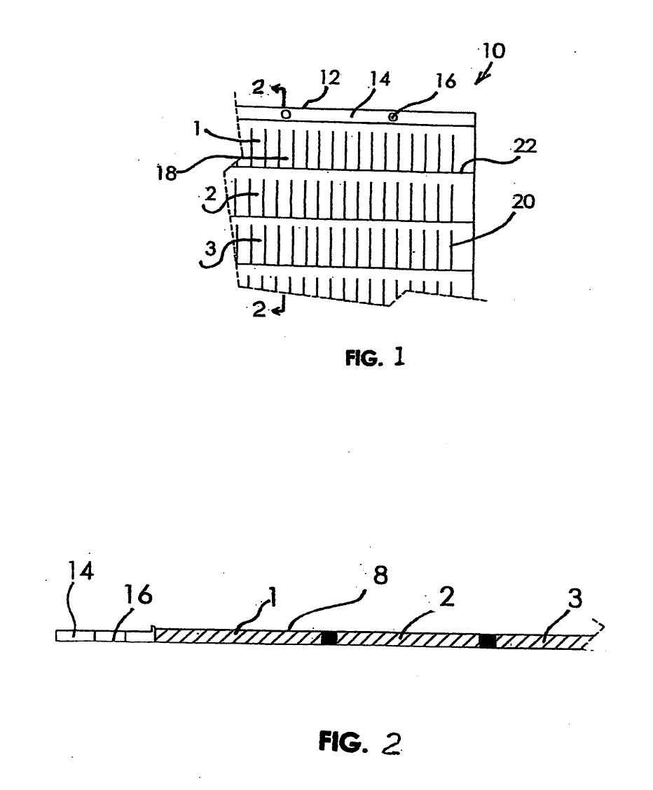

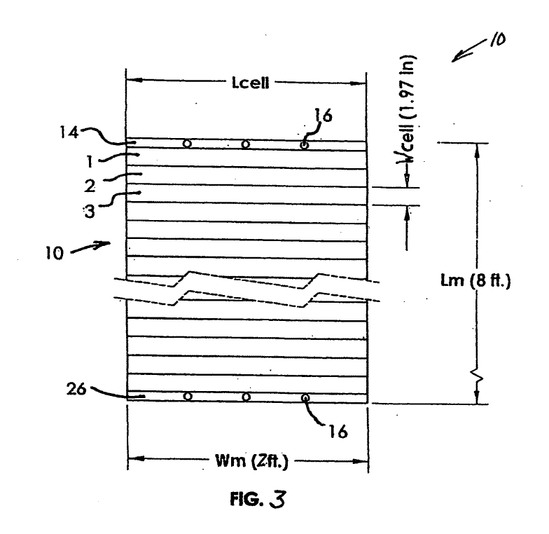

FIG. 2 is a sectional depiction from the perspective of lines 2-2 of FIG. 1. The FIG. 2 embodiment shows a series connected arrangement of multiple photovoltaic cells 1, 2, 3, etc. To promote clarity of presentation, the details of the series connections and cell structure are not shown in FIG. 2. Suitable interconnection structure is taught in the above-referenced Luch patents.

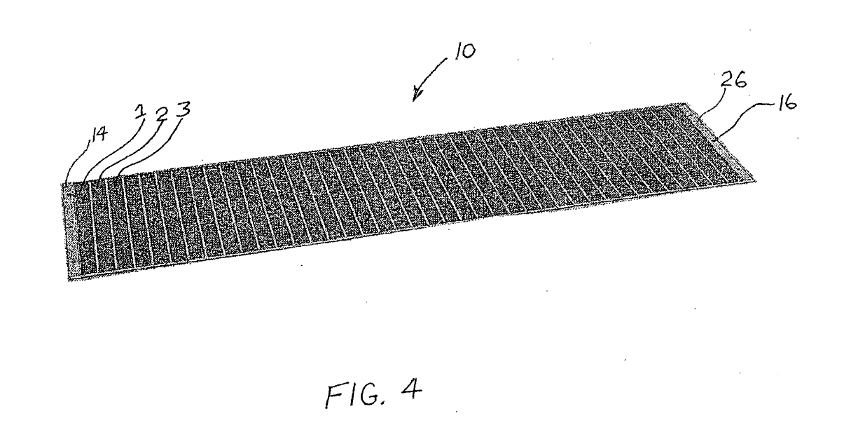

FIG. 3 is a simplified top plan view showing typical overall structural features of a module embodiment. In the FIG. 3 embodiment, typical overall module surface dimensions are indicated to be 2 ft. width (Wm) by 8 ft. length (Lm). In the following, module dimensions of 2 ft. Wm by 8 ft. Lm may be used to teach and illustrate the various features and aspects of certain embodiments of the invention. However, one will realize that the invention is not limited to these dimensions. Module surface dimensions may be larger or smaller (i.e. 2 ft. by 4 ft., 4 ft. by 16 ft., 8 ft. by 4 ft., 8 ft. by 16 ft., 8 ft. by 100 ft., etc.). There is great latitude in choice of module dimensions or overall form factor, the choice being made to accommodate overall system requirements.

In the FIG. 3 embodiment, a photovoltaic module is generally indicated by numeral 10. Module 10 has terminal ends defined by length dimension “Lm”. At opposite terminal ends of the module are terminal bars 14 and 26. Mounting through holes 16 are positioned through the terminal bars 14, 26 as shown in FIG. 2. The module embodied in FIG. 3 has three holes 16 on each of the terminal bars 14 and 26. It will be shown that these holes also may contribute to establishing electrical contact to a current carrying bar electrically connecting multiple modules. Thus, the multiple holes may contribute to redundancy and security of contact.

In the FIG. 3 embodiment, the module is indicated to have a length (Lm) of 8 ft. However, the module comprises multiple individual cells having surface dimensions of width (W cell) (actually in the defined length direction of the overall module) and length (L cell) as shown. In some embodiments such as that of FIG. 3 the length of the individual cell (L cell) is considerably greater than its width (W cell). Typically cell width (W cell) may be from 0.2 inch to 12 inch depending on choices among many factors. For purposes of describing embodiments of the invention, a typical cell width (W cell) is suggested as 1.97 inches in FIG. 3 while the cell length (L cell) is suggested to be 2 ft. In the FIG. 3 embodiment, the cell length (L cell) is shown to be substantially equivalent to the module width (Wm). In addition, terminal bars 14, 26 are shown to span substantially the entire length (L cell) of the end cells.

The module embodiment 10 of FIG. 3 having an overall length (Lm) of 8 ft. comprises 48 individual cells interconnected in series, with terminal bars 14 and 26 of about 0.7 inch width at each terminal end of the module. Assuming an individual cell open circuit voltage of 0.5 volts (typical for example of a CIGS cell), the open circuit voltage for the module embodied in FIG. 3 would be about 24 volts. This voltage is noteworthy. Lower voltages, for example less than 50 volts, pose reduced risk of electrical shock. Thus, 24 volts is insufficient to pose a significant electrical shock hazard. Furthermore, the opposite polarity terminals of the FIG. 3 module are separated by 8 feet, reducing the risk of accidental simultaneous contact. Should higher voltages be permitted or desired, one very long module or multiple modules connected in series may be considered, employing installation and connection structures taught herein for the modules. Alternatively, should higher voltage cells be employed (such as multiple junction a-silicon cells which may generate open circuit voltages in excess of 2 volts), the cell width (W cell) may be increased accordingly to maintain a safe overall module voltage. At a ten percent module efficiency, the module of FIG. 3 would generate about 148 Watts.

FIG. 4 is an overall perspective view of a module similar to that embodied in FIGS. 1 through 3. The structures embodied in FIGS. 1 through 4 may be absent rigid components and thus may be characterized as flexible. A flexible structure will typically deform under small force but can be returned to substantially its original shape upon removal of the force

One realizes the module structures depicted in FIGS. 1 through 4 may in some cases be employed without further modification. For example, they may be readily fabricated at a factory and shipped in bulk packaging form to an installation site. In other cases additional components may be incorporated at the factory prior to shipment.

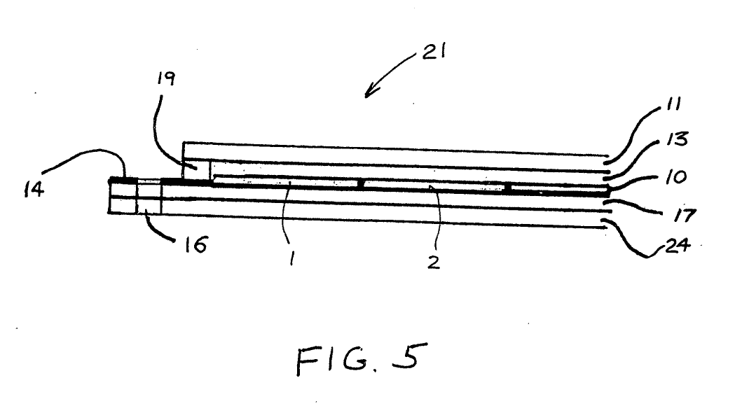

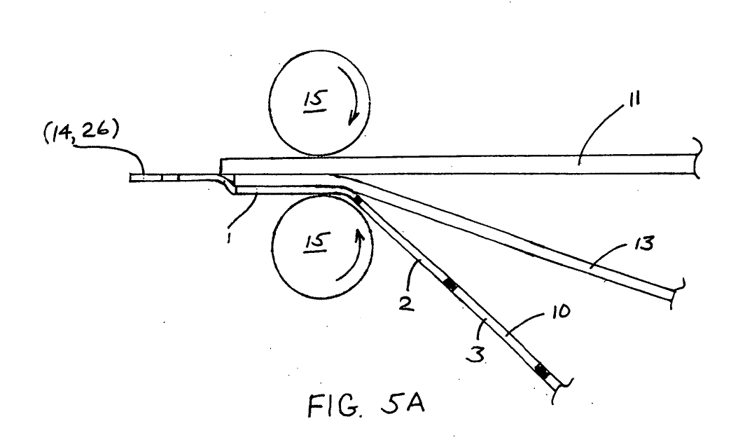

FIG. 5 embodies a module structure having additional added components. In FIG. 5, a modified modular structure is generally designated by numeral 21 to reflect these added components. FIG. 5 shows a transparent barrier sheet 11 and optional encapsulant or sealant layer 13 applied to the light incident upper surface of an original module structure 10 such as embodied in FIGS. 1 through 4. Transparent sheet 11 may comprise glass or a flexible barrier film. Sheet 11 may comprise multiple layers imparting various functional attributes such as environmental barrier protection, adhesive characteristics and UV resistance, abrasion resistance, and cleaning ability.

Prior to application of layers 11 and 13, the original module structure 10 may be flexible. In that case, regardless of whether sheet 11 is flexible or rigid, it may be applied to the module using roll lamination as depicted in FIG. 5A. Glass sheets would normally be considered rigid. Polymer sheets of thickness greater than about 0.025 inch are generally described as rigid. As one understands, the roll lamination depicted in FIG. 5A may have manufacturing benefits compared to other lamination processes such as batch vacuum lamination. In the roll lamination process of FIG. 5A, the sealant 13 may be heated sufficiently to soften and form a seal between the facing surfaces of the original module structure 10 and sheet 11. Rolls 15 squeeze the warmed composite together to form this surface seal while at the same time expelling a majority of air. In this process the sheets may be preheated prior to entering the rolls or the rolls themselves may be heated to sufficiently soften the sealant layer 13. Alternatively, the sealant 13 may comprise a pressure sensitive adhesive and the process of FIG. 5A may be practiced at room temperature.

Sealant layer 13 may comprise a number of suitable materials, including pressure sensitive adhesive formulations, ionomers, thermoplastic and thermosetting ethylene vinyl acetate (EVA) formulations and the like.

It is understood that once the original module structure 10 is applied to transparent sheet 11, the composite will behave mechanically similar to the transparent sheet. Should sheet 11 be rigid, as is typical for glass or a thick plastic sheet, the composite (structure 10/sealant 13/transparent sheet 11) would be characterized as rigid. Should sheet 11 be flexible, as is typical for a thin plastic sheet, the composite may remain flexible.

It is emphasized that the roll lamination process depicted in FIG. 5A is but one form of process capable of creating the resulting structure. Other lamination techniques, such as vacuum lamination or simple spreading of sealing material followed by transparent sheet application, may be alternatively employed. In some embodiments, layer 13 may be eliminated and module 10 simply “tacked” to sheet 11.

Returning now to FIG. 5, there is shown additional sheetlike structure 17 beneath the (structure 10/sealant 13/transparent sheet 11) composite. In the FIG. 5, numeral 17 points to a “backsheet” structure. Backsheet 17 may typically be attached to structure 10 using sealing or adhesive material (not shown). Backsheet 17 functions to provide environmental protection and optionally protection against electrical hazard. Typically, the backsheet is sufficiently expansive to underlay the entirety of the one or more strings of interconnected cells comprised by the module.

A number of different backsheet structures exist. For example, backsheet 17 may comprise glass. Alternatively, backsheet 17 may comprise a flouropolymer film or a multilayered structure such as aluminum foil layered onto polyethylene terpthalate (PET). Backsheet 17 may be chosen to be either rigid or flexible. One will understand that it may be possible to apply backsheet 17 simultaneously with sheets 11 and 13 during the lamination process depicted in FIG. 5A, especially if either or both backsheet 17 and sheet 11 are flexible.

Also shown in FIG. 5 is an optional supporting structure 24. Structure 24 may also supply environmental and electrical protection. The supporting structure 24 may be rigid or flexible and may comprise any number of material forms, such as polymeric sheet, a honeycomb structure, expanded mesh, wire mesh or even weatherable plywood. Supporting structure 24 may comprise a composite structure of more than one material. Structure 24 may also incorporate heat conveyance structure to assist in cooling the module. The laminate structure (transparent sheet 11/sealant 13/modular structure 10/backsheet 17) may be attached to the support 24 using standard techniques such as structural adhesives. It is understood that structure 24 is optional and may possibly be omitted, especially if the module is to be attached to other supporting structure such as a roof or other support structure.

Also shown in FIG. 5 embodiment is sealant strip 19 positioned outside a perimeter defined by the active light absorbing cell surface. In the embodiment, strip 19 is adjacent the periphery of transparent sheet 11. The strip of sealant 19 normally comprises a moisture barrier such as butyl rubber. An additional strip of desiccant material (not shown in FIG. 5) may optionally be placed within the boundary defined by sealant strip 19 in order to absorb any moisture which may migrate through the sealant strip during the life expectancy of the modular construction. In other embodiments, sealant strip 19 may be supplemented or replaced by extending sealant 13 outside a perimeter defined by the active light absorbing cell surface.

In an embodiment of the invention, a construction similar to that of FIG. 5 is employed but with the elimination of sealant layer 13. This construction leaves a slight air space between the surface of module 10 and sheet 11 but has exhibited excellent performance in accelerated testing when used in conjunction with an internal desiccant as described above.

In FIG. 5, through hole 16 is seen to extend through terminal bar 14, backsheet 17 and supporting structure 24. As will be seen, through holes 16 may provide a convenient structure with which to achieve electrical connection and attachment to an eventual installation structure.

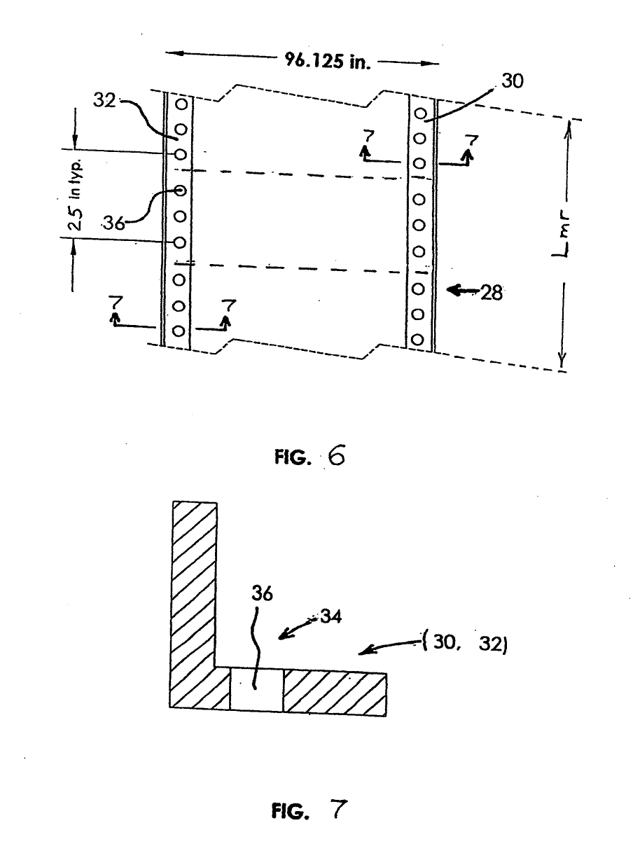

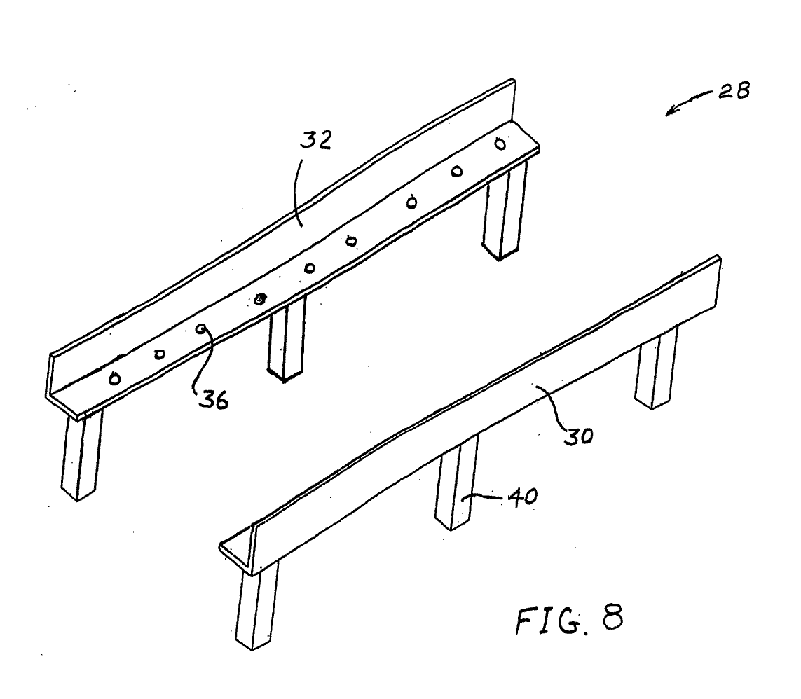

FIG. 6 is a top plan view of a portion of one form of field installation structure, generally indicated by numeral 28. FIG. 7 is a sectional view taken substantially from the perspective of lines 7-7 of FIG. 6. FIG. 8 is a perspective view of the portion 28. In the structural and process embodiments herein described, installation structures may be pre-constructed at the site prior to combination with modules 10 such as depicted in FIG. 1 through 4 or module 21 as depicted in FIG. 5. For example, should a terrestrial installation be desired, appropriate land grading and support construction could be completed in advance of the arrival of the modules.

FIGS. 6 and 8 show that the installation structure 28 comprises two parallel elongate rails 30 and 32. In this embodiment, rails 30 and 32 are oriented, spaced and have structure appropriate to readily receive modules. For example, in the embodiment of FIG. 6 the rails have an open or “receiving” dimension (shown as 96.125 inch in the embodiment) slightly larger than a length dimension (Lm) of the FIG. 3 module. The outline of a module such as that of FIG. 3 is depicted in phantom by the dashed lines in FIG. 6. The rails 30, 32 will normally extend a distance (Lmr) greater than the combined aggregate width of a multiple of the expansive surface area photovoltaic modules. A center-to-center distance among modules is suggested as 25 inches in the FIG. 6, indicating about a 1 inch spacing between adjacently place modules.

FIG. 7 is a sectional view taken substantially from the perspective of lines 7-7 of FIG. 6 and shows the details of one form of structure for rails 30, 32. In the FIG. 7 embodiment the rails comprise a 90 degree angle structure of an elongate form of metal such as aluminum. The angle forms a seat 34 to receive the photovoltaic module. Holes 36 through the metal rails are sized and spaced to mate with the holes 16 in modules 10 or 21. Holes 36 may have a smooth bore or be structured such as with a thread pattern to receive a threaded mounting bolt.

The rails may be supported above a base, roof or ground level by piers or posts 40 supported by the ground or solid surface such as a roof. This elevation allows air flow beneath the modules to cool the relatively thin sheetlike modules. Further, the rails 30, 32 may be at different elevations so as to tilt the arrays at a given angle according to the latitude of the installation site. It is further noted that in this FIG. 7 embodiment and many others taught in this specification the installation structure may be absent ground or surface penetrating structure.

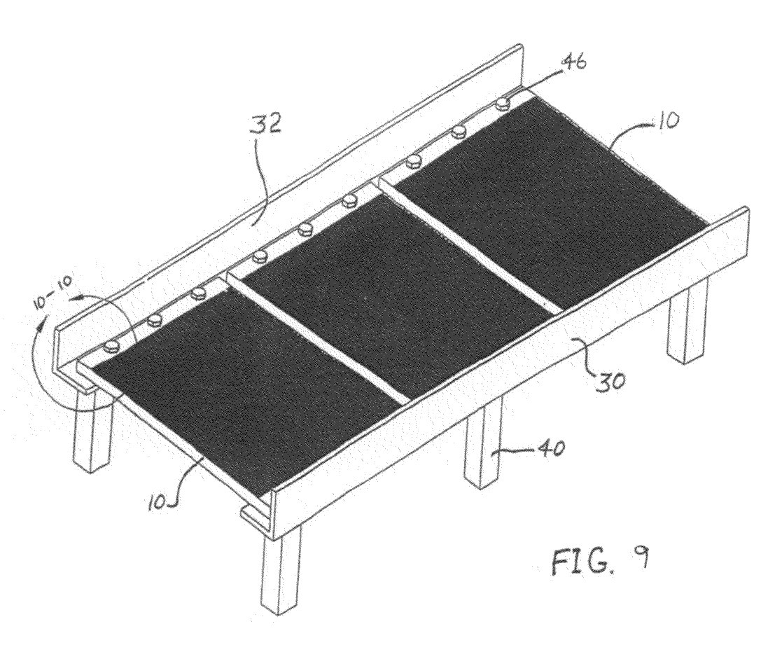

FIG. 9 shows the result of attaching multiple modules (3 in the FIG. 9 embodiment) to the elongate rail structure. The rails have a structure which mates dimensionally with the sheetlike structure of the modules such that the sheetlike modules (10 or 21) are easily positioned appropriately with respect to the rail structure. Electrical connection between the terminal bars 14, 26 disposed at the two opposite ends of the module (10 or 21) and the rails 30, 32 is simultaneously achieved through the mechanical joining of the module to the rails. The terminal bars of a first polarity end of the multiple modules are attached to a first rail and the terminal bars of the opposite polarity are attached to the second opposing rail. It is noted that in this embodiment the multiple modules are connected to rails such that each rail serves as a common manifold for conveyance of power associated with multiple modules and there is no need for coupling of components from the adjacent modules. Thus, current accumulates in the rails as they span multiple modules but the voltage is envisioned to remain substantially constant.

In preferred embodiments the rails 30,32 comprise rigid, elongate metal forms. For example, rails 30, 32 may comprise extruded material forms comprising metals such as aluminum, copper or metal alloys which are relatively inexpensive, rigid, strong and have high conductivity. Most forms of these metals, except for small cross sectional wires and thin sheets, may be characterized as rigid. In this specification and claims, the term rigid is intended to mean a form that is firm and stiff. The rails can comprise more than one metal or alloy. Surface coatings or treatments or additional materials known in the art may be employed to prevent environmental corrosion and deterioration of contacts. As will be shown in the embodiments of FIGS. 8 through 10, the mounting rails 30, 32 may function as power conduits or primary busses from a multiple of individual photovoltaic modules. In order to manage resistive heating losses using such parallel connections among modules, a convenient rule of thumb is that the cross sectional area of the rails be greater than about 0.1 square inch (i.e. 0.1 sq. inch, 0.2 sq. inch, 0.5 sq. inch, 1.0 sq. inch) for every 500 amperes of current conveyed. Elongate forms of most metals and alloys, specifically aluminum, copper and steel, having such cross sections would normally be considered rigid.

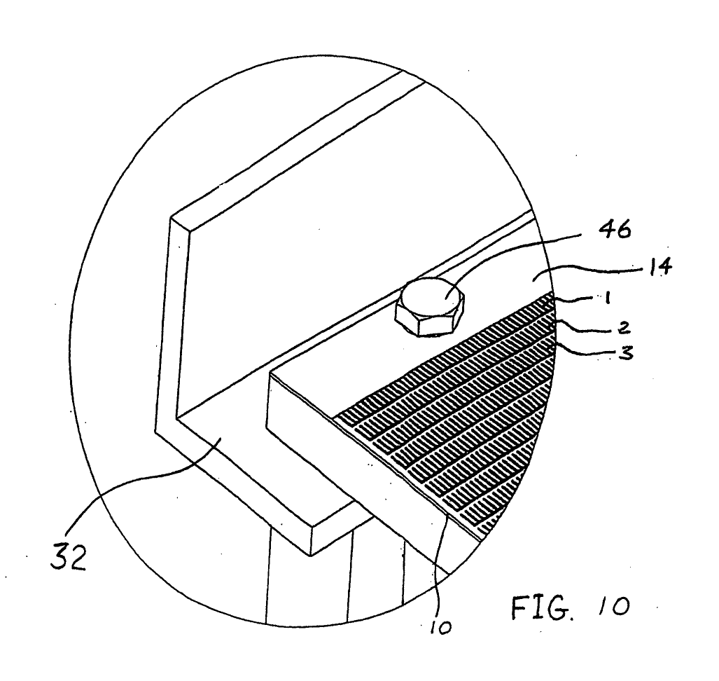

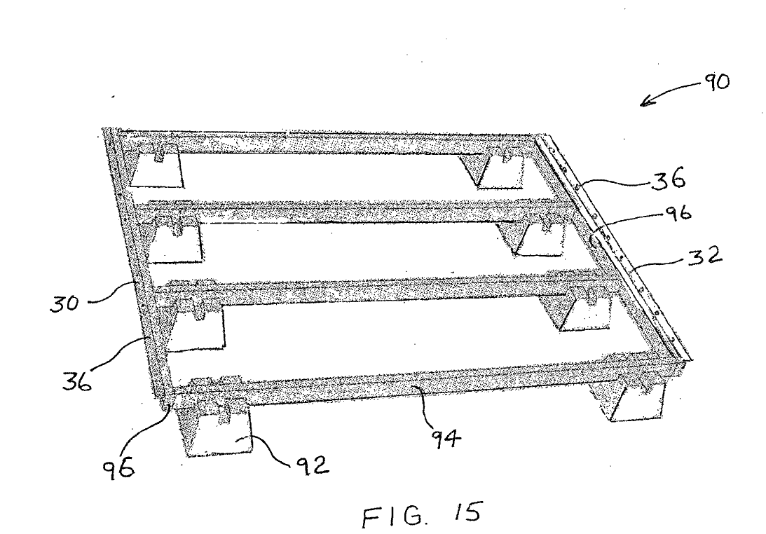

FIGS. 10 through 14 embody details of examples of mechanical joining which simultaneously accomplishes electrical communication between terminal bars 14, 26 and rails 32, 30. The FIGS. 10 and 11 show that the modules are quickly and easily secured to the angled rails using mechanical fasteners such as the metal bolts 46 shown extending through the oppositely disposed module terminal bars, the module support and the metal angle rails. Other conductive mechanical fasteners may be employed such as rivets, clips, banana plugs, expansion bolts (toggle bolts for example) and metal anchors. For example, a spring clip 47 achieves electrical and mechanical connection to flat rails (32a, 30a) in the FIG. 13 embodiment. Banana plug 45 achieves electrical and mechanical connection to the rails (30,32) in the FIG. 14 embodiment. It is noted that the modules depicted in the FIGS. 10, 11, 13 and 14 are shown with supporting structure 24 but are absent components 11 (transparent sheet), 13 (sealant) and 17 (backsheet). The omission of components 11, 13, and 17 is done here for clarity of presentation. One understands that components 11, 13 and 17 may be included without affecting the basic mounting concepts presented in FIGS. 10, 11, 13 and 14.

Other hardware and materials (not shown in the Figures) such as washers and conductive compounds known in the art may be considered to improve surface contact between the conductive mechanical fasteners, terminal bars 14, 26 and rails 32,30. One appreciates that the fasteners should comprises non-corrosive materials such as stainless steel or titanium or employ surfaces and materials assuring longevity of contact. It is noteworthy that no wires or metal ribbons are required to achieve this simultaneous mechanical and electrical joining. Thus there is no need for electrical leads such as unwieldy wires or ribbons emanating from the module. Further there is no need for processes such as soldering to achieve the mechanical and electrical mounting, although such techniques are clearly optional. The mechanical fasteners shown in the FIGS. 10, 11, 13, and 14 embodiments are very robust, quick and simple to install and provide a low resistance connection resistant to breakage and environmental deterioration. In FIG. 9, multiple bolts 46 at each module end (3 shown) minimize contact resistance between the module terminal bars 14, 26 and the angle material and provide redundancy of contact. In this way the power generated in the expansive module is transferred to the supporting rails 32, 30. Thus module mounting and electrical connection to the rail “power conduit” is achieved easily and quickly without any separate wiring requirement. In addition, the mechanical mounting and electrical connection envisioned allows facile removal and replacement of a module should it become defective or future technology produces largely improved performance justifying such replacement.

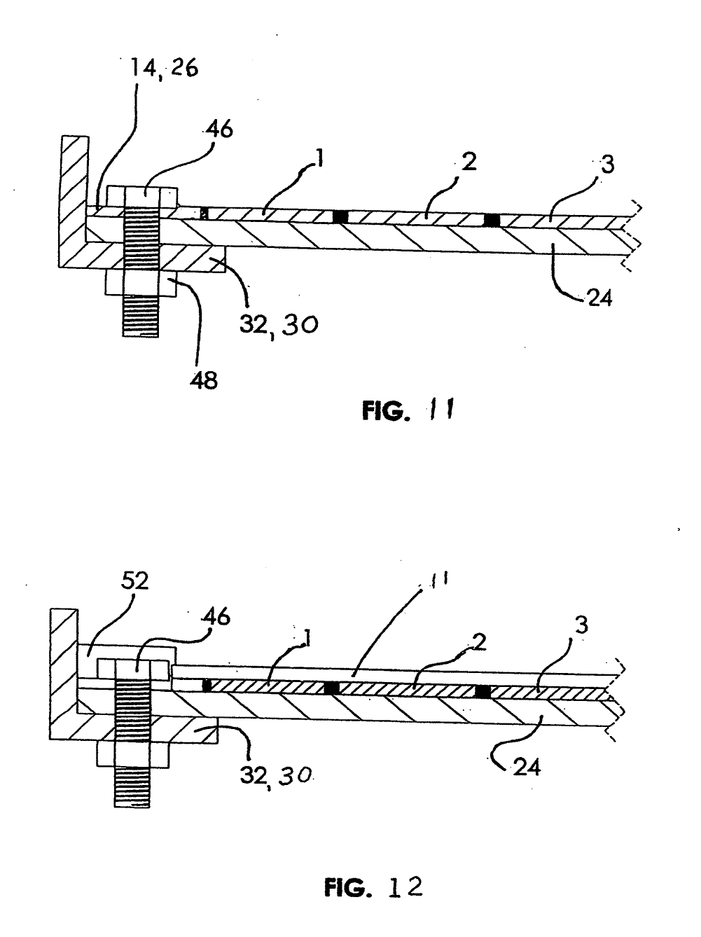

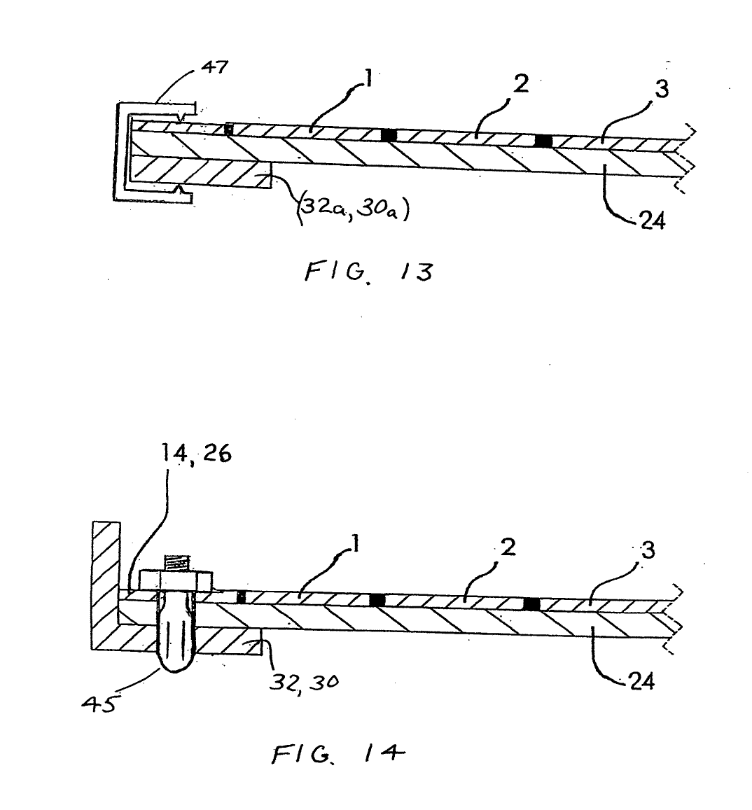

FIG. 12 embodies a structure similar to FIG. 11 but including an additional rigid or flexible, sheetlike transparent cover 11 for the module which may comprise glass or a transparent polymer sheet such as polycarbonate, acrylic, or PET. As stated above, the purpose on the transparent sheet is to afford additional functional attributes to the module such as environmental protection, abrasion resistance, and cleaning ability. Certain thin film semiconductors such as CIGS are susceptible to environmental deterioration and can be protected by such a transparent environmental cover. It is envisioned that protective cover sheet 11 may be installed after installation of the photovoltaic module to installation structure. Alternatively, the cover 11 may be applied at the factory prior to shipment and site installation. It is further envisioned that a sealing member, such as depicted by numeral 52 in FIG. 12, may be employed to fix the transparent sheet in position, provide edge sealing, and further protect the terminal bars and fastening hardware. It may be advantageous for such a sealing member 52 to be semi-permanent, such as would be the case for a conformable weather stripping material. In this way the module may be easily removed and repaired or replaced as necessary.

As shown in FIG. 9, multiple sheetlike modules (10 or 21) are attached to the rails repetitively in a linear direction along the rails. Each of the modules produces substantially the same voltage, but the current increases each time the rails span an additional module. In this way the installation is a simple placement of the expansive surface modules relative the supporting rails and the mechanical fastening of the modules to the rails (using conductive, mechanical joining means such as nuts and bolts) allows current to flow from the individual module to the rails, with the rails also serving as a conductive buss or power conduit of high current carrying capacity. The elongate rails lead to a collection point where the accumulated power is collected and optionally transferred to a larger master buss for additional transport or the power is converted from “high current/low voltage” to “high voltage/low current” power to achieve more efficient transport.

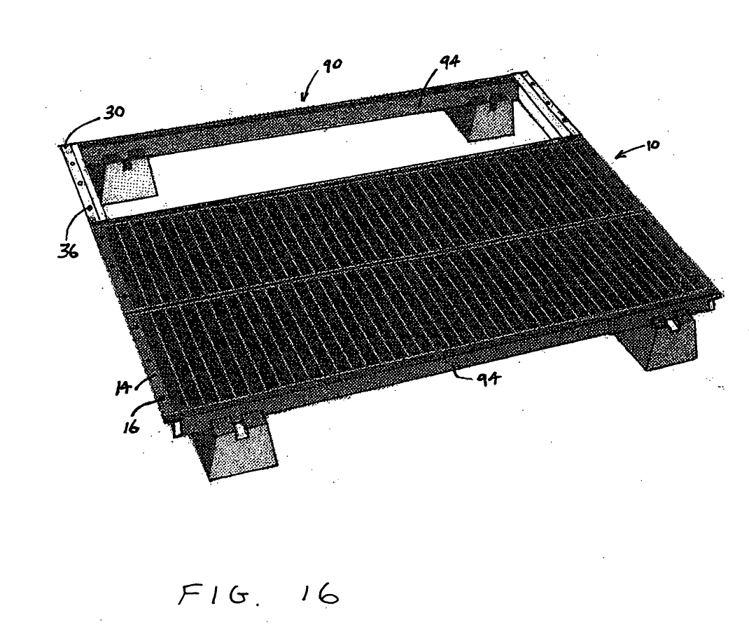

Turning now to FIG. 15, there is shown a perspective view of another embodiment of installation structure generally indicated by the numeral 90. Installation structure 90 comprises piers 92 which may comprise the familiar concrete piers used for deck construction. Alternative materials such as recycled polymers may also be employed for construction of such piers. The piers serve not only to support a support lattice above a base surface but may also serve as a weigh ballast to stabilize the structure against environmental conditions. In the embodiment of FIG. 15, the piers are grooved to allow placement of lateral support bars 94. Many choices such as wood, tubular metal or plastics, composites, may be considered for bars 94. Structure 90 also comprises longitudinal support bars 96 extending between multiples of bars 94 as shown. Attached to bars 96 are metal rails (30,32) having mounting holes 36. In this embodiment the rails comprise metal angles mounted to bars 96, oriented to present a flat metallic surface extending outward from the bars 96. In aggregate, structure 90 can be described as a lattice supported and stabilized by piers 92 above a base surface. Additional structure may be included as required to structure 90. For example, additional structural integrity and support may be achieved by additional bars extending between adjacent bars 94 or by attaching a wire mesh screen over the base lattice bars.

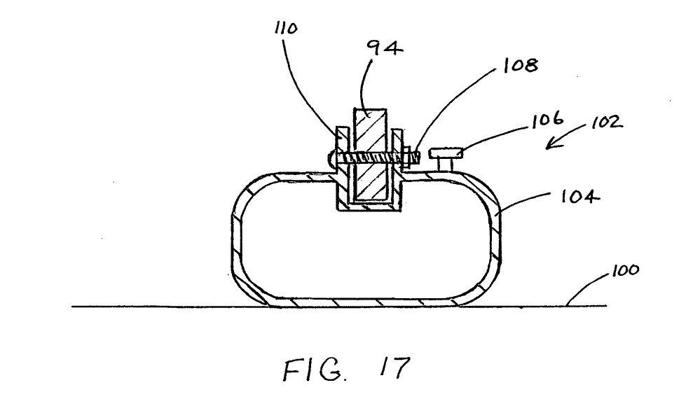

FIG. 16 illustrates the mounting of modules 10 (2 modules shown in FIG. 16) to the installation structure 90. Holes 16 in the terminal bars of the modules match with holes 36 in the rails (30,32). Conductive mounting hardware (not shown in FIG. 15) electrically and mechanically attach the module to the support structure. Current is conveyed by the rails (30,32) which function as common basses for the assembly of multiple modules.

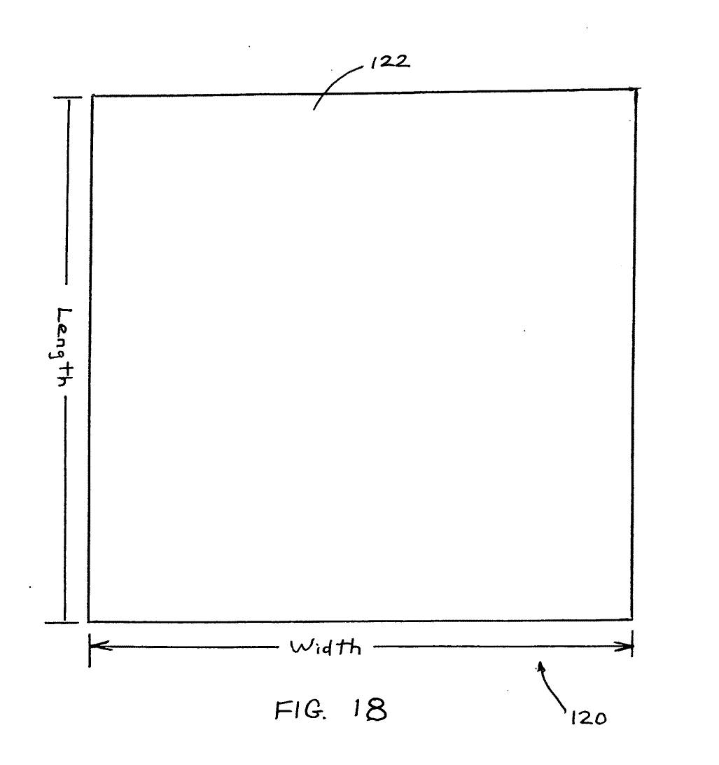

FIG. 17 shows another embodiment of structure 102 to support a lattice-like structure above a base surface 100. Structure 102 comprises a tank 104 having a fill spout and closure 106. Support bars 94 may be attached to tank 104 using standard attachment concepts. In the FIG. 17 embodiment, attachment is achieved using a bolt 108 extending through tank flange 110 and bar 94. Thus, the tanks 104 replace or supplant the posts 40 (FIG. 8) or piers 92 (FIG. 15). In use, tank 104 is filled with liquid such as plain water to supply weight ballast. This arrangement allows shipment and assembly of lightweight components at the installation site and then adding the stabilizing weight to the structure by simply filling the tanks 104 with liquid.

Tank 104 may be constructed from plastic or metal using standard tank manufacturing techniques. Plastic blow molding or injection molding are preferred processes for inexpensive, high volume manufacturing of suitable tanks. Plastic molded tanks are durable and capable of exposure to harsh environments for extended periods.

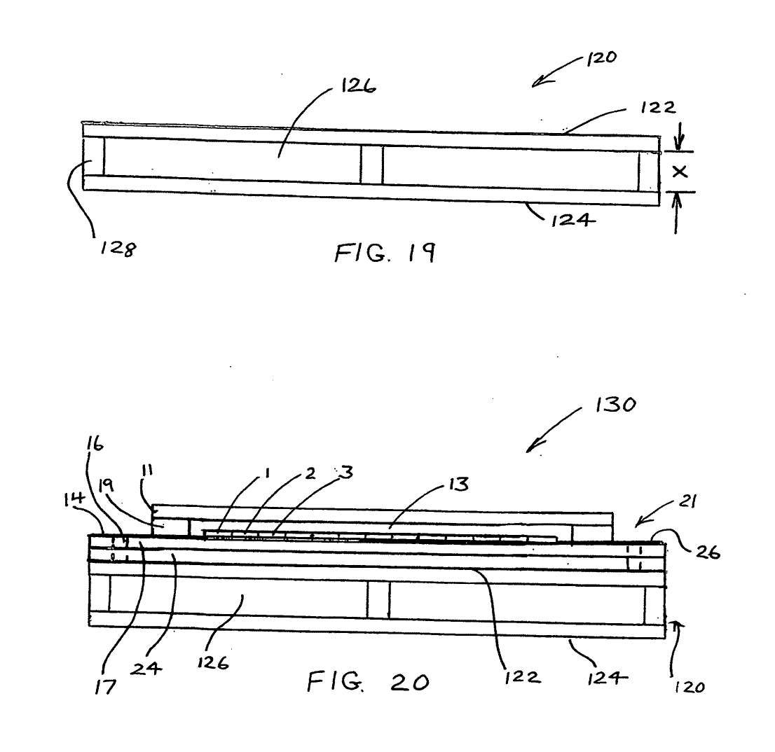

FIG. 18 is a top plan view of another embodiment of a installation structure identified as 120. FIG. 19 is a side view of installation structure 120. It is seen that structure 120 comprises a substantially flat top surface 122 and a bottom surface 124. Surfaces 122 and 124 may be solid and formed by continuous sheets of material. Alternatively, surfaces 122 and 124 may be discontinuous and formed by positioned slats, lattice, mesh and the like. Between the materials forming surfaces 122 and 124 is air space 126. The positioning separation between materials forming surfaces 122 and 124 is maintained by positioning spacers or blocks 128.

Referring to FIG. 18, structure 120 has a length and width as indicated. The installation structures 120 are sized to underlie one or more modules, and thus normally have a top surface area 122 of about 4 square feet or greater. Typical dimensions for both the length and width of structure 120 are 42 inches by 42 inches respectively. Referring to FIG. 19, dimension “X” shown may be typically 4 inches. Given these dimension, one will recognize that structure 120 closely resembles a standard shipping pallet. Such a structure may be easily moved using standard forklift equipment. It also may be easily stacked, transported and distributed. Moreover, structures such as 120 may be easily and readily produced using inexpensive methods such as blow molding, injection molding and thermoforming. Finally, commodity materials such as plastics or wood may be employed. Structure 120 and similar structures may be referred to as “pallets” in the following.

Referring now to FIG. 20, there is shown in side view a combination of the module of FIG. 5 and the “pallet” installation structure 120 of FIG. 19. In the FIG. 20 embodiment, the modular structure 21 is mounted onto installation structure 120. In the FIG. 20 embodiment, installation structure 120 underlies substantially all of modular structure 21. The overall combination can be characterized as an installation unit and is generally indicated by the numeral 130 in the FIG. 20. It can be readily understood that this combination offers the transport and distribution advantages of palletized material along with the positioning, rigidity, and stability of a fixed permanent support structure. One further realizes that installation unit 130 may be substantially completed in a factory remote from the final installation site and transported to the site for final combining with additional units to form a final stationary power installation. In addition, while both support sheet 24 and material forming surface 122 are shown in the FIG. 20, one will recognize that these two components could readily be combined into a single component (i.e. the support sheet 24 could also be the material forming top surface 122 of the “pallet” installation structure).

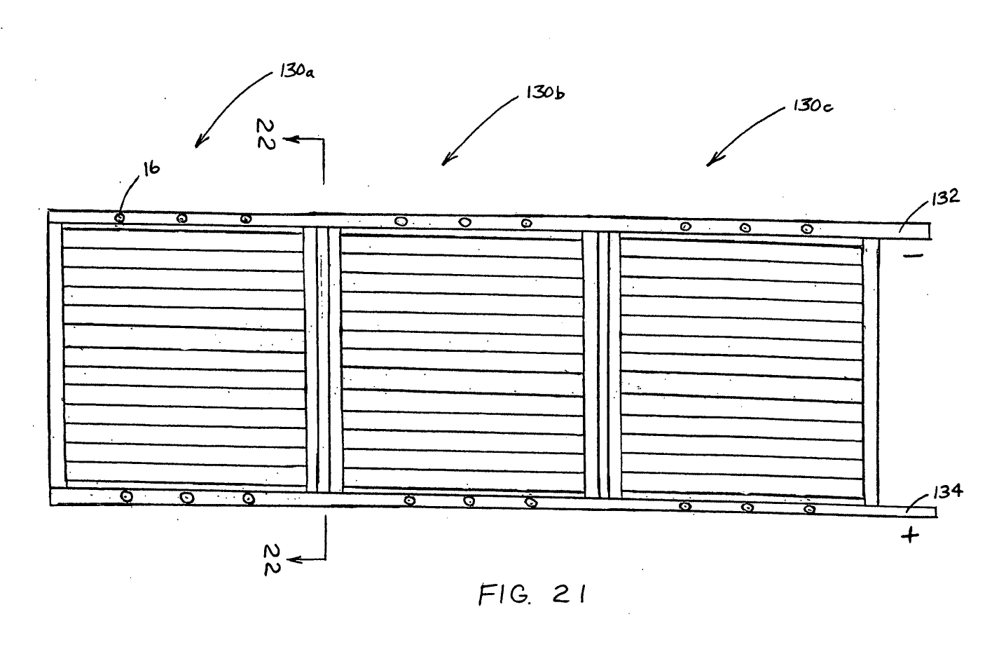

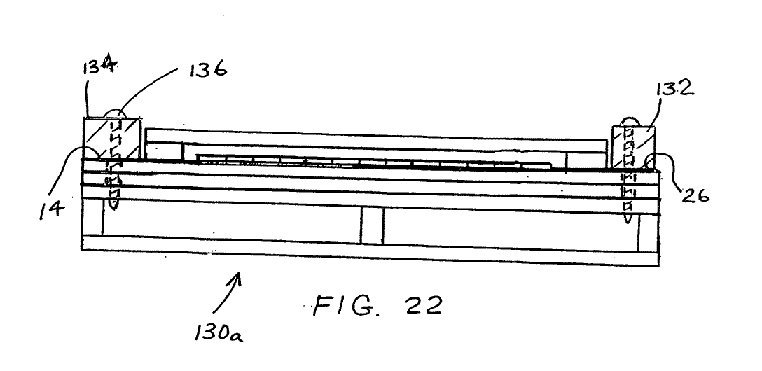

FIG. 21 is a top plan view of an assembled array of 3 of the “pallet” installation units (130a, 130b, 130c) of FIG. 20. FIG. 22 is a side view, partially in section, taken from the perspective of lines 22-22 of FIG. 21. Referring to both FIGS. 21 and 22, it is seen that the array of multiple modules is achieved by simply placing the “pallet” installation units side by side and then interconnecting them with metallic rails 132 and 134. Each of the rails (132,134) contacts and connects the terminal bars (14,26) from a multiple of adjacently positioned modules 130. The mechanical connection of the rails to the module terminal bars and the underlying “pallet” installation structure is shown to be achieved using simple screws 136. The downward force imparted by the screws also brings the rails (132,134) into electrical contact with the module terminal bars (14,26). Simultaneously, the attachment of the rails to the support “pallets” maintains their adjacent positioning and the long term stability and integrity of the entire assembled array of interconnected modules. In practice, the rails 132, 134 serve to both collect and convey power from the assembly of modules and also serve to tie the installation units together in a secure group. Alternatively, elongate rails may be used to bind multiple units together without being also associated with power conveyance. In that case the rails could be constructed of an insulating material such as plastic.

One will realize the structure depicted in FIG. 17 could readily be extended to create a structure of pallet like characteristics. For example, one could simply replace the positioning blocks 128 with small tanks such as embodied in FIG. 17. This would combine the light weight, transportable and modular advantages of the “palletized” module with the convenient weight ballast and stability offered by the liquid filled tanks taught in conjunction with the FIG. 17 embodiment.

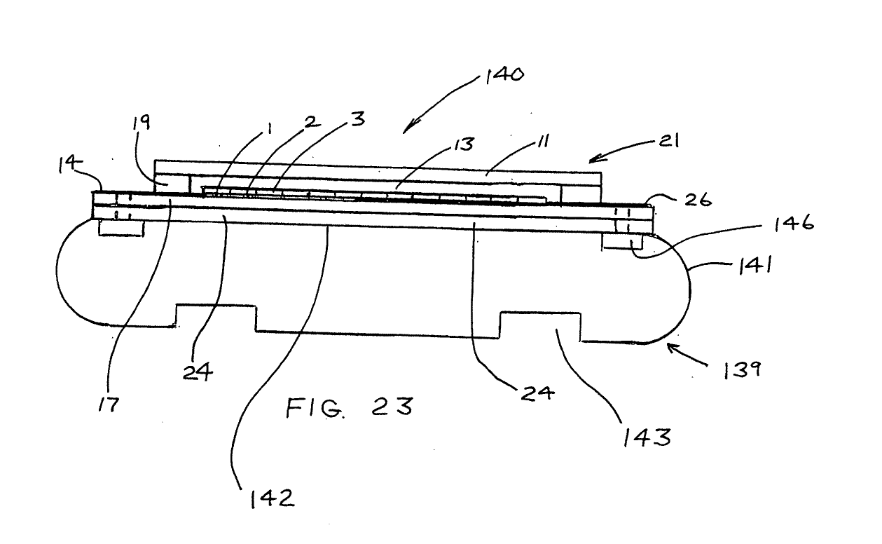

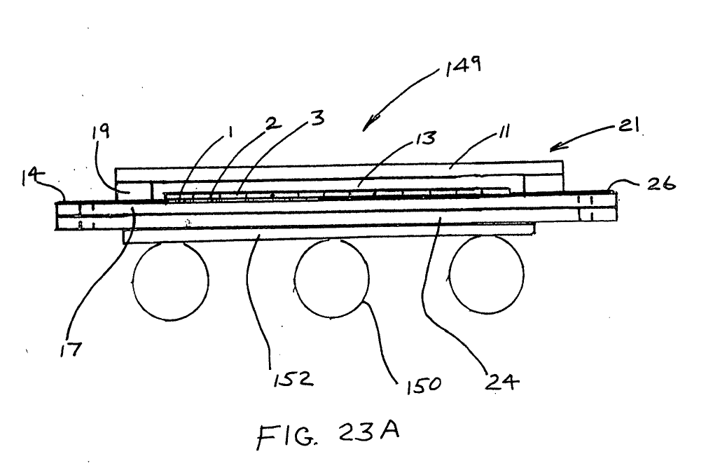

Referring now to FIG. 23, there is embodied yet another form of “palletized” installation unit. The article of FIG. 23, generally designated by the numeral 140, comprises a combination of the module 21 as in FIG. 5 with a large surface area tank-indicated by numeral 141. Tank 141 comprises a number of important features. It is-hollow and can contain liquid. Absent liquid, the tank 141 is relatively light weight and therefore the combination article 140 is relatively light weight. However, when the tank is filled with liquid such as water, the combination article 140 significantly increases in weight. In the FIG. 23 embodiment, tank 141 has overall dimensions comparable to a conventional pallet, as was the case for the “pallet” of FIGS. 18 and 19. Tank 141 also has depressions or grooves 143 formed in its bottom to accommodate the forks of a forklift. Tank also has formed indentations 146 to accommodate extending hardware (such as a toggle bolt) used to attach a metal rail to the terminal bars (14,26) of module 21. These features can be easily incorporated into plastic tanks produced by conventional blow molding or two part injection molding processing.

To produce the article 140, one simply applies a module such as that of FIG. 5 to the top surface of tank 141. Standard structural adhesives may used to adhere the module and tank together. It is noted that because the tank may be rigid, support sheet 24, while shown in FIG. 23, may possibly be eliminated from this combination. The combination articles 140 are transported to the installation site and are arranged adjacent each other. Metal rails, similar to rails 132, 134 of FIG. 22, may be employed to span and interconnect multiple modules. The interconnection may be similar to that shown in FIGS. 21 and 22. However, in the embodiment of FIG. 23, hardware used to electrically and mechanically attach the rails to the terminal bars must not penetrate the tank, so indentations 146 are present to allow extending hardware such as expansion or toggle bolts and rivets. The tanks may then be filled with water or other material to supply ballast and stability to the entire array of interconnected modules.

It has been observed that a liquid such as water supplying ballast in the assembly 140 heats up significantly during the exposure to solar radiation. Thus the arrangement 140 shown in FIG. 23 may also serve as a source of both heated water and electricity. In this regard it is anticipated that tank 141 could be replaced by a grouping of tubes attached to a sheet which itself is attached to module 21. In this case water would be slowly passed through the tubes to generate a continuous stream of hot water during daytime hours and simultaneously cool the modules to give improved electrical performance. An embodiment of an installation unit having such an arrangement, generally identified 149, is illustrated in FIG. 23A. Tubes 150 are secured in geometrical arrangement by sheet 152. Sheet 152 is adhered to the underside of module 21. Water is slowly passed through the tubes at a rate sufficient to heat the water to a desired temperature. Simultaneously, electrical power is collected at terminal bars 14 and 26.

It is noted with reference to FIG. 23A that support sheet 24 shown may be considered for elimination, replaced by sheet 152. It is further noted that proper selection of sheets 11, 17 and 152 would readily permit structure 149 to remain flexible and easily transportable.

One notes that the tank and tube-like structures embodied in FIGS. 23 and 23A could also be constructed to contain a lightweight liquid or gaseous material such as air. In that case, one may propose using the combination assemblies such as 149 and 140 as floating structures employed over water surfaces.

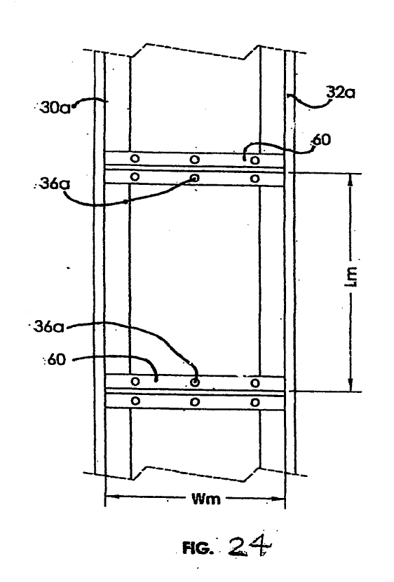

Referring now to FIG. 24, another embodiment of an installation structure according the invention is shown in top plan view. This structural embodiment also comprises rails 30a, 32a. In the FIG. 24 embodiment, rails 30a, 32a need not be electrically conductive as will be understood in light of the teachings to follow. Additional cross rails 60 span the separation between rails 30a, 32a. These cross rails 60 have an elongate structure as shown and in an embodiment may be electrically conductive. The repetitive distance between the elongate cross rails is slightly greater than the length (Lm) of a module (for example 96.125 inch for a module of eight foot length). Cross rails 60 also comprise holes 36a which, as will be seen, are positioned to mate with complimentary holes extending through the terminal bars of modules to be eventually positioned on the FIG. 24 structure. Finally, the rails are characterized as having a width dimension (Wm) slightly larger than the width of the eventual module. Thus the rails 30a, 32a, 60 form a convenient receptacle or frame within which a module may eventually be positioned.

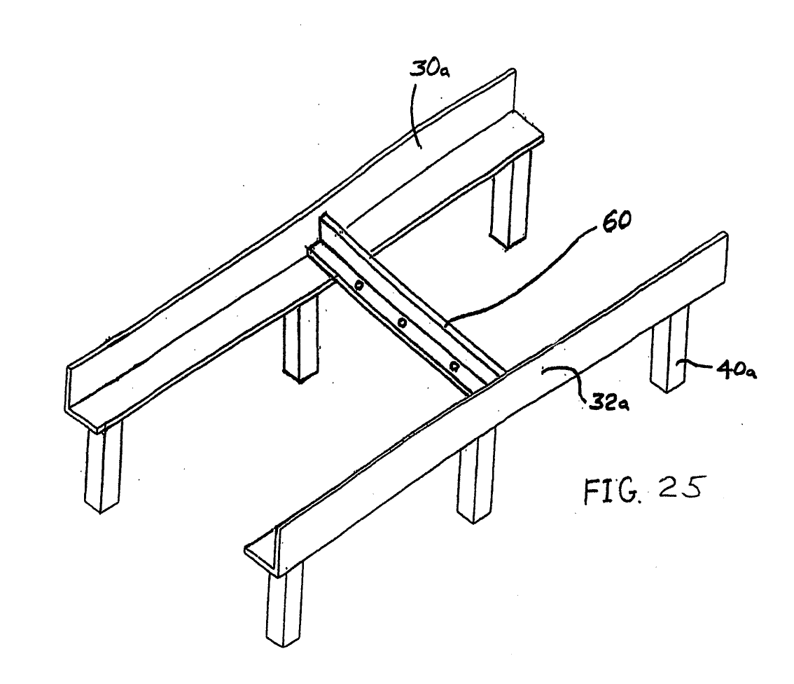

FIG. 25 is a perspective view of a portion of the FIG. 24 structure. In FIG. 25 it is seen that the rail structure 30a, 32a, 60 may be supported on stilts 40a above a base level as previously illustrated for the FIG. 8 embodiment.

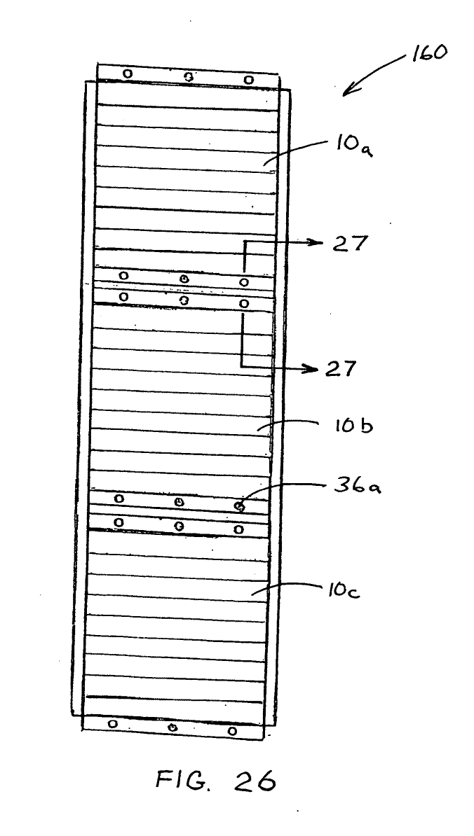

FIG. 26 is a top plan view showing modules 10a, 10b, 10c mounted on the structure of FIGS. 24 and 25. This arrangement is generally indicated by the numeral 160. Holes 36a in the rails 60 align with holes in the module terminal bars. This allow fastening hardware to extend through the holes and accomplish both fastening and electrical communication between the terminal bars of modules and conductive rails.

FIG. 27 is a view in partial section taken substantially from the perspective of lines 27-27 of FIG. 26. In this FIG. 27 embodiment, elongate cross rail 60 comprises electrically conductive material, normally a metal. Two modules are generally indicated in FIG. 27 by the numerals 10a, 10b and the individual series connected cells by the numerals 1a, 1 b, etc. FIG. 27 shows that cross rail 60 has the shape of an inverted “tee” having holes 36a on arms 49 and 62 of the “tee”. The terminal bar 14a of module 10b is fastened to a first arm 49 of the “tee” form of cross rail 60 using conducting metal threaded bolts 46a and nuts 48a. The head 47a of bolt 46a contacts a top conductive surface of terminal bar 14a. Additional washers and conductive compounds (not shown) may be used as appropriate to improve surface contact between fastener features and conductive surfaces. Application of the nut 48a securely fastens module 10b to the arm 49 and supplies electrical communication between terminal bar 14a and arm 49. A similar fastening arrangement secures and electrically connects the terminal bar 26a of module 10a to the second arm 62 of cross rail 60. Since in this embodiment the cross rail 60 is conductive, electrical communication is established between terminal bar 14a of module 10b and opposite polarity terminal bar 26a of module 10a. The two modules are thereby simply, inexpensively and robustly connected in series.

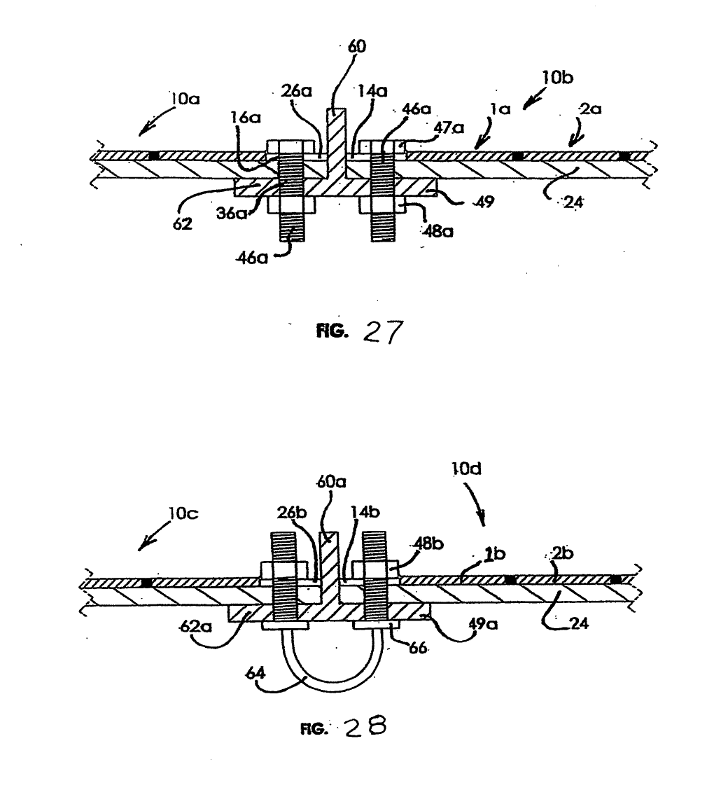

FIG. 28 shows an arrangement partially in section similar to FIG. 27 but illustrating a different form of fastening and connection. In the FIG. 28 embodiment, cross rail 60a is seen to be of cross section similar to that of cross rail 60 in FIG. 13. However, in the FIG. 28 embodiment, elongate cross rail 60a need not necessarily comprise conductive material. In FIG. 28, first terminal bar 14b of module 10d is secured to a first arm 49a of cross rail 60a using one end of a “U-bolt” type connector. In the embodiment, secure attachment of module 10d to rail 60a is achieved by threading of nut 48b such that it pulls flange 66 tightly against the bottom of arm 49a as shown. A similar attachment is made to terminal bar 26b of module 10c. Contact of the respective nuts 48b with the upper conductive surfaces of terminal bars 14b and 26b of modules 10d and 10c respectively connect the two modules in series through the rigid conductive “U-bolt” fastener. Module mounting is rapid, inexpensive and simple.

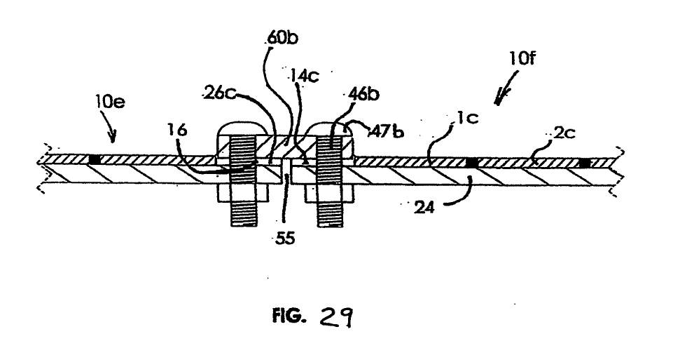

FIG. 29 shows another embodiment of a series connection among adjacent modules. In FIG. 29 the “tee” shaped rails 60 or 60a of FIGS. 27 and 28 respectively are replaced by a simple flat rail in the form of a strap 60b. Modules 10e and 10f may have a slight separation between them as shown at 55 but are in close enough proximity to be described as adjacent. Electrically conductive rail 60b in the form of a conductive metal strap is positioned over the top of terminal bars 14c and 26c on the adjacent modules 10e. Strap 60b has through holes positioned to mate with the through holes on terminal bars 26c and 14c of modules 10e and 10f respectively. Electrically conductive fasteners, in the FIG. 29 embodiment “carriage” type threaded bolts 46b, then secure the strap rail to both terminal bars and thereby a secure and robust electrical connection between terminal bars 26c and 14c is achieved. Simultaneously, the two modules 10e and 10f are affixed in adjacent positioning.

It will be understood that the modules 10 of the embodiments shown in FIGS. 26 through 29 may comprise additional function components such as those presented in the discussion of FIG. 5. These include a transparent cover sheet, sealant layers, backsheets and bottom support layer as previously described in the discussion of the FIG. 5 embodiment.

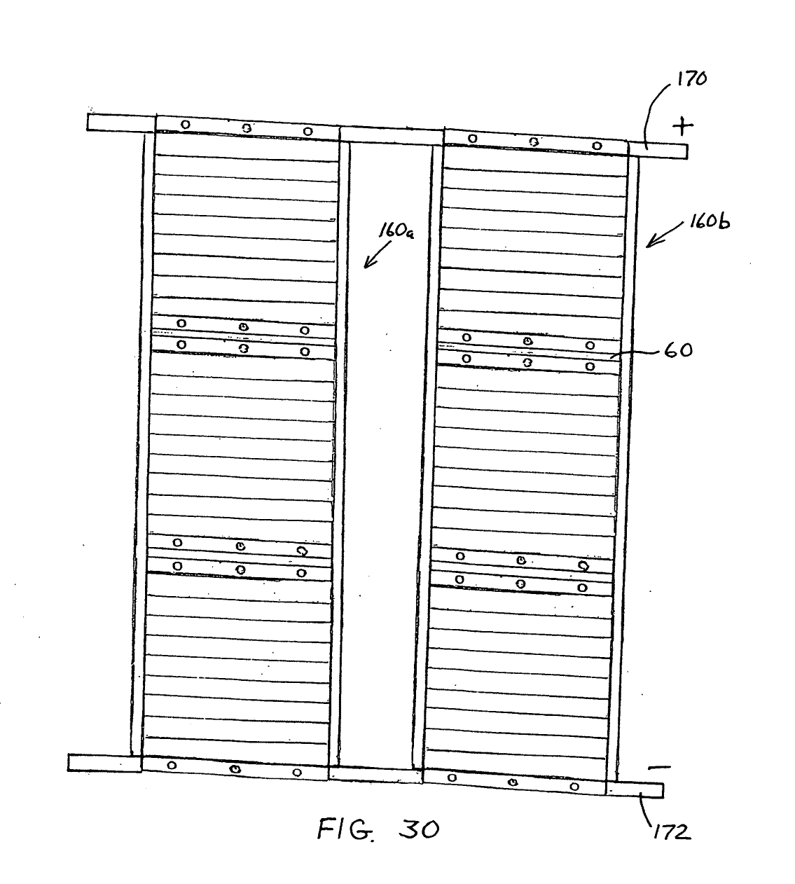

FIG. 30 shows an installation combining the parallel module connections of FIGS. 9, 16, 21 with the series module arrangement illustrated in FIG. 26. In FIG. 30, assemblies of multiple modules connected in series, as depicted in FIG. 26, are indicated by the numerals 160a, 160b. These series connected multi-module assemblies are themselves connected in parallel using conducting busses 170,172 and the techniques taught in regard to FIGS. 8,16 and 21. Conducting busses 170, 172 convey the collected power to a site for central collection or additional processing.

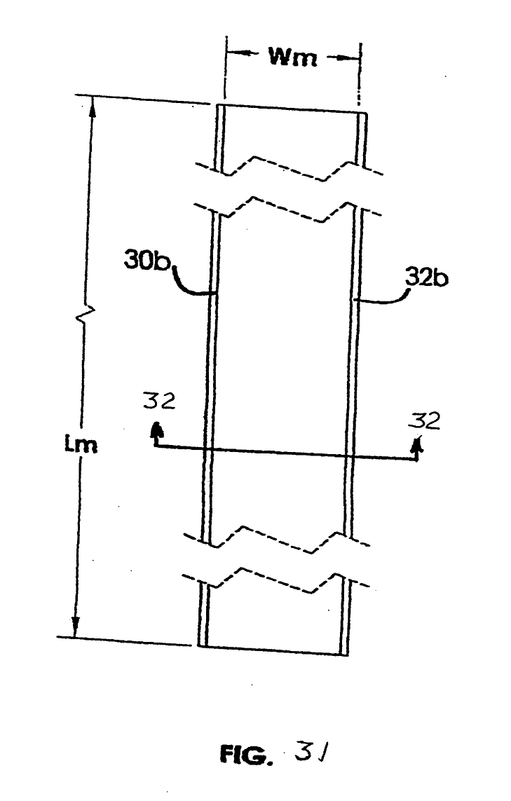

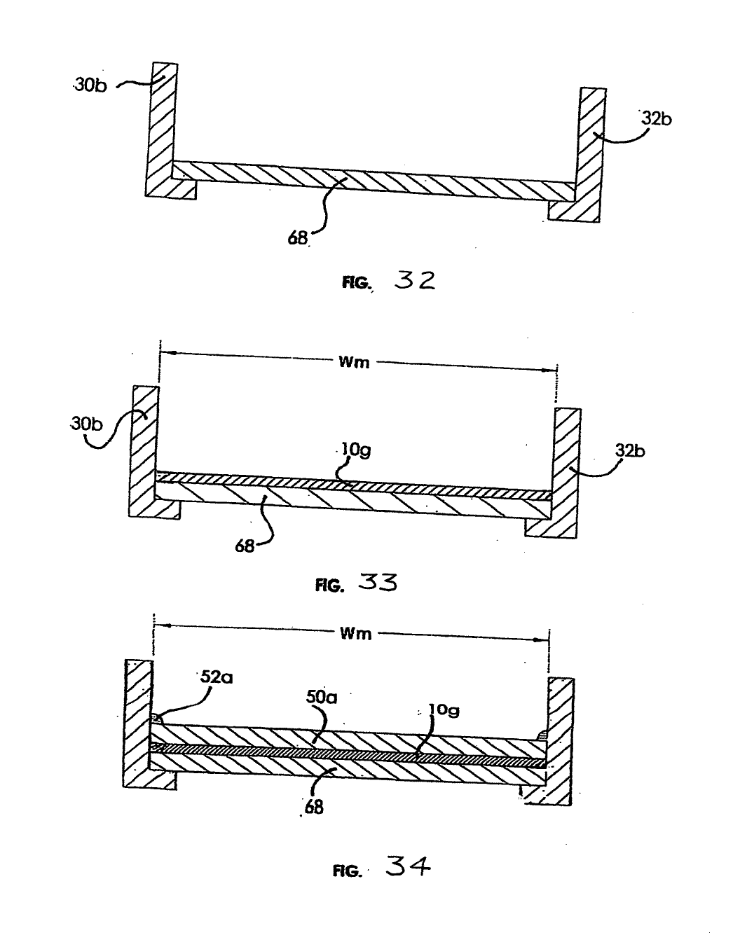

FIG. 31 is a top plan view of another structural embodiment of the inventive installations of the instant invention. FIG. 32 is a sectional view taken substantially from the perspective of lines 32-32 of FIG. 32. Reference to FIGS. 31 and 32 shows a structure comprising a pair of elongated rails 30b and 32b spanned by a rigid supporting sheet 68. Supporting sheet 68 may comprise any number of materials and forms, including honeycomb or expanded mesh forms. Sheet 68 may also be a composite structure of multiple materials and forms, such as backsheet materials and sealants. The combination of rails 30b, 32b, and sheet 68 is seen to form an extended channel, which as will be seen has a width slightly larger than the width of the eventual applied photovoltaic module structure. One will also understand that this channel may be supported above a ground surface by piers, stilts etc. as previously taught for prior embodiments.

Continued reference to FIG. 31 suggests that the structure is receptive to a single module having a relatively long length (Lm). Indeed, such a structure may serve as an installation structure to receive and support a module of extended length. While prior art modules have restricted surface dimensions due to fabrication limitations and materials of manufacture, the referenced teachings of the Luch patents and disclosures introduce materials and forms capable of practical production of modules having extended dimensions, particularly in the length direction. Luch teaches technology to produce modules having a length limited only by the ability to properly accumulate them in a roll form. Modules having length in feet of two to three figures (i.e. 10 ft., 50 ft. 100 ft. 1000 ft.) are entirely reasonable using the Luch teachings. Modules having such extended length may be considered “continuous” and transported and installed in roll form. Thus, the dimension (Lm) in FIG. 31 may be considered to be of such extended dimension. Width “Wm” in FIG. 31 may correspond to a module width dimension which may be manageable from a handling and installation standpoint. By way of example, “Wm” may be less than 10 ft. (i.e. 1 ft., 2 ft., 4 ft., 8 ft.) but widths “Wm” greater than 10 ft. are certainly possible.

FIG. 33 is a sectional view similar to FIG. 32 following application of a extended length (continuous) form of photovoltaic module 10g. It is envisioned that such a module would be conveyed to the installation site and simply rolled out following the outline of the channel frame formed by rails 30b, 32b and support 68 which is clearly shown in FIG. 32. An appropriate structural adhesive (not shown in FIG. 33) may be used to fix the module 10g securely to sheet 68.

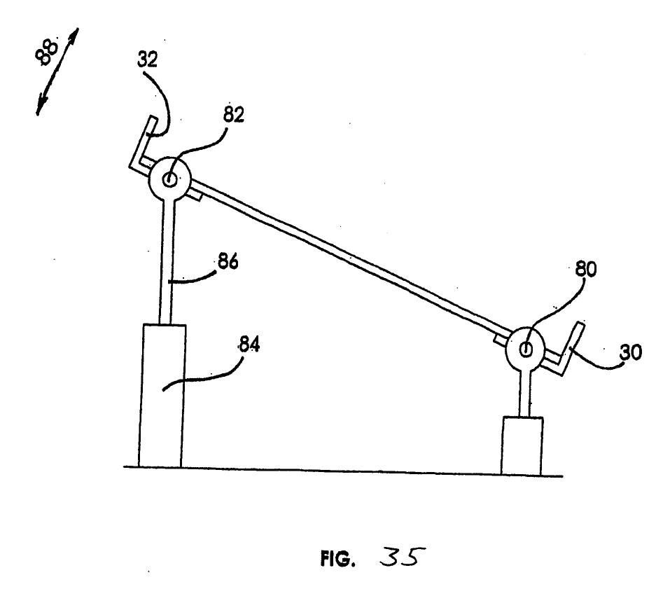

FIG. 34 is a view similar to FIG. 33 but after application of an optional transparent cover sheet 50a and sealing material 52a. As has previously been explained, sheet 50a and sealing material 52a may be useful in extending the life of certain environmentally sensitive photovoltaic materials.

In the supporting structure embodiments shown herein, some embodiments depict “rail” members, in the form of material having angled cross sections. While one will realize that such a cross section is not necessary to accomplish the structural and connectivity aspects of the invention, such a geometry forms a convenient recessed pocket or frame to readily receive the sheetlike forms being combined with the structures. In addition, the vertical wall portion of the angled structure offers a containment or attachment structure for appropriate edge protecting sealing materials.

### CONCEPTUAL EXAMPLES

### Example 1

Modules of multiple interconnected cells comprising thin film CIGS supported by a metal foil are produced. Individual multi-cell modules are constructed according to the teachings of the Luch U.S. patent application Ser. No. 11/980,010. As noted, other methods of module construction may be chosen. Each individual cell has linear dimension of width 1.97 inches and length 48 inches (4 ft.). 48 of these cells are combined in series extending approximately 94.5 inches in the module length direction perpendicular to the 48 inch length of the cells. Such a modular assembly of cells is expected to produce typical electrical components on the order of 26 open circuit volts and 18 short circuit amperes. A terminal bar is included to connect to the bottom electrode of the cell at one end of the 8 ft. module length. A second terminal bar is included to connect to the top electrode of the cell at the opposite end of the 8 ft. length. The terminal bars are readily included according to the teachings of the referenced Luch patent application Ser. No. 11/980,010. The terminal bars need not be of extraordinary current carrying capacity because their function is only to convey current a relatively short distance and to serve as a convenient structure to interconnect to adjacent mating conductive structure. The individual modules may include appropriate support structure and protective layers as taught above.

In a separate operation, a terrestrial site is selected and prepared. The site may be optionally graded to form a landscape characterized by a combination of repetitive elongate hills adjoining elongate furrows. The linear direction of the elongate hills and furrows and the inclination angle from the base of a furrow to the peak of an adjoining hill is adjusted according to the latitude of the site and possible drainage requirements, as those skillful in the art will appreciate. Piers or stilts are situated to emanate from the ground. (Alternatively, the piers or stilts may be of different heights to accomplish a modular tilt if desired). The piers are positioned repetitively along the length of the hills and furrows. As an example, the piers may be positioned repetitively separated by about 4 to 8 feet, although this separation will be dictated somewhat by the strength of the eventual supporting structure spanning the distance between piers. Finally, a supporting structure, including the elongate rails such as the angled rails as described above, are attached to the piers extending along the length of the hills and furrows. The supporting structure need not be excessively robust, since the modules are relatively light. Should rail strength or current carrying capacity be of concern, other structural forms for the rails, such as box beam structures or increased cross sections, may be employed. Indeed, increased rail cross section may become appropriate as rail length increases.

Installation proceeds by repetitive placement and securing multiple module sheets along the length of the rails. The thin film modules are relatively light weight, even at expansive surface areas. For example, it is estimated that using construction as depicted in FIGS. 5, a 2 ft.×8 ft. module of this example 1 would weigh less than 50 pounds. Thus easy and rapid mounting may be achieved by a 2 man team.

Should the mounting of the modules be in a parallel arrangement such as depicted in FIGS. 9 and 16, the elongate rails are constructed of conductive material such as aluminum or copper. Expected current increases in increments with the placement of each individual module but the expected voltage stays substantially constant along the length of the rails. The expected open circuit voltage from the 2 ft. by 8 ft. conceptual module is about 26 volts, not enough to pose an electrical shock hazard. In addition, the oppositely charged rails are separated by 8 ft. Thus the oppositely disposed rails need not be heavily insulated.

A typical length for the rails may be greater than 10 ft. (i.e. 50 ft., 100 ft., 200 ft., 300 ft.) As the expected current increases at greater length, the cross sectional area of the supporting rails may also be increased to accommodate the increasing current without undue resistive power losses. The rails thus serve as the conduit to convey photogenerated power from the multiple modules in parallel connection to a defined location for further treatment.

Should the modules be arranged in series, as depicted in the embodiments of FIGS. 26 through 29, voltage will increase along the length of the installation structure but the current will remain substantially constant. In the case of the example modules (2 ft.×8 ft. module with cell widths of 1.97 inches and length of 24 inches), the current will remain at about 18 amperes as the power is collected through the multiple modules mounted in series. However, open circuit voltage will increase by about 26 volts as the power traverses each 8 ft. length of module. For a 96 ft. accumulated length of modules, the open circuit voltage will have accumulated to about 312 volts. Thus, in this case precautions must be observed regarding electrical shock danger.

### Example 2

In this example, site preparation is generally similar to that of Example 1 and structures are constructed according to the embodiment of FIG. 31. Modules are manufactured and shipped to the installation site in the form of rolls of extended length. For example, a continuous roll of CIGS cells interconnected in series to form a single module is produced. Individual cells have a width dimension of 1.97 inches and length of 48 inches. The module is 100 ft. in length and has terminal bars at each end of the 100 ft. length. There are 608 series connected cells and the terminal bars are about 1 inch wide and extend across substantially the entire 48 inch width of the module. The modules are accumulated in rolls each of which comprises a 100 ft. module as described.

The rolls are shipped to the installation site. There, workers position one end at the start of an extended channel such as depicted in FIGS. 31 and 32. The module is unrolled using the channel as a guide, optionally using a structural adhesive to fix the module to the supporting structure. A 100 ft. roll of thin film module on a 0.001 inch metal foil substrate is estimated to weigh less than 40 pounds so that the installation could proceed with as little as a two man crew. Electrical connections to a buss bar mounted on the channel's end may be made using the electrically conductive fasteners and techniques such as taught hereinbefore

The extended length module has a total active surface area of 400 square feet. It would be expected to generate approximately 3600 or more peak watts. Output current would be only about 15 amperes so that conductors need not be overly robust. Closed circuit voltage would be about 310 volts so that safety precautions and security concerns would have to be addressed.

In a comparison of the conceptual examples, the parallel mounting arrangements presented in FIGS. 6, 9, 16, and 21 have the advantage of low shock hazard, easy installation and module replacement. However, this arrangement requires attention to conductor cross sections to minimize resistive losses from high currents. The series arrangement presented in FIG. 26 has the advantage of low currents and therefore low costs of conductors. This arrangement also is characterized by relatively facile installation and replacement. However, this arrangement is characterized by possible high voltage accumulation and requires protection against shock potential. Finally, the extended length module arrangement of FIGS. 31 through 34 may be the simplest installation requiring a minimum of interconnections and facile module shipping and placement. This arrangement produces high voltage buildup and more difficult replacement of defective cells or portions of modules.

Finally it should be clear that while the installation structures illustrated in the embodiments accomplish supporting modules above a base surface such as the ground or roof, the installation principles taught herein are equally applicable should one use a roof or other surface to support the module.

An additional embodiment of the instant invention is presented in FIG. 35. In the FIG. 35 arrangement one of the rails 30 is mounted on a pivoting support 80. This pivoting support 80 may comprise a simple hinge as an example. Indeed, should plastic materials be employed, the pivoting support 80 may be a simple as a well-known “living hinge”. The opposite rail 32 is also mounted to a pivoting support 82. In the FIG. 35 embodiment, pivoting support 82 is further mounted to a jacking device 84 as shown. The jacking device 84 may be as simple as a variable extension rod. Alternatively, the jacking device 84 may comprise automated adjusters employing a motorized jack screw or even a hydraulic cylinder. The jacking device 84 provides adjustable extension which accomplishes rotation of the module along an arc generally indicated by double ended arrow 88. Thus, the multiple modules mounted on rails may be conveniently tilted appropriately according to positional latitude or season. In the case of flexible thin film modules which can be relatively large yet lightweight this tilting mechanism may be accomplished with a minimum of complexity.

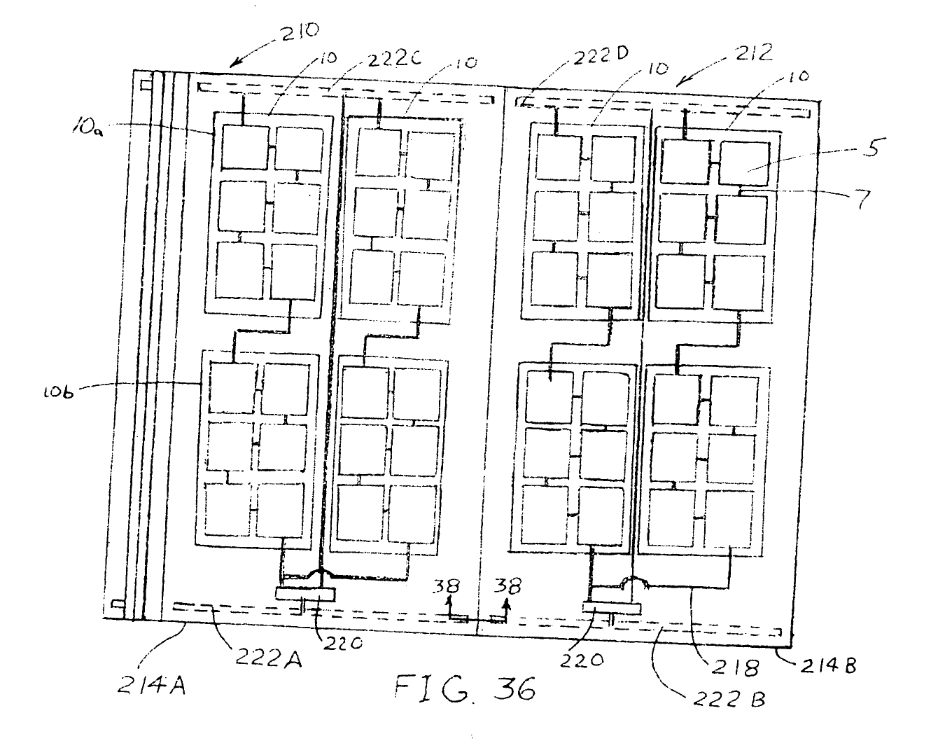

Turning now to FIG. 36, there is shown a top plan view of an embodiment of photovoltaic installation including photovoltaic modules and installation structure. The FIG. 36 embodies two installation units generally designated 210 and 212. Each installation unit comprises one or more photovoltaic modules 10 mounted to installation structures 214A and 214B. In this embodiment the modules 10 comprise series connected strings of individual photovoltaic cells 5. Installation structures 214A and 214B extend beneath the modules as mounting and support structure for the modules. Electrical conductor 7 extends between individual cells. As with the installation structure 120 embodied above, the installation structures 214 may be of standardized design and produced using mass production processing such as injection molding, blow molding, thermoforming. Commodity materials such as plastic and wood along with standardized construction techniques may be employed. This reduces the cost of installation structures. Further, as with the units 130, 140, and 149 embodied in FIGS. 18-23A, one realizes that installation units 210, 212 may be substantially constructed in a factory remote from the final installation site and transported to the site for final combining with additional units to form a final stationary power installation. The units themselves can be characterized as “portable” in that they can be conveniently transported to a final site. After transport and arrangement at the final site, multiple units may be combined in an expansive area of photovoltaic collection. The combined multiple units will typically be non-portable.

One may appreciate that many of the attributes of installation structures 214 are similar to those of the installation structures of FIGS. 18 through 23A. However, the installation structures 214 of FIGS. 36 through 38 embody additional features integrally incorporated into the design of the installation structure. These features may improve power conditioning, power transport or interlocking/positioning of adjacent units to achieve facile installation.

In the FIG. 36 embodiment, each unit is shown comprising four modules 10 wherein “pairs” of modules (such as 10a,10b) are connected in series. The power from the series connected pair is conveyed by conductor 218. In the embodiment, the power output of two “pairs” are combined in parallel, and the combined power is fed to a power conditioning device 220. One realizes that many different modular configurations and arrangements are possible. The power conditioning device alters the power characteristics to facilitate collection, conveyance, and use. For example, the power conditioning device may boost voltage to reduce resistance power losses during subsequent power transport. In other applications, the direct current power from the photovoltaic modules may be converted to alternating current along with voltage alteration.

As noted above, packaging of the electronics may be responsible for a significant portion of the cost of a conventional power conditioning device. One notes that the power conditioning of the FIG. 36 embodiment may be incorporated as an integral component of the installation structure underlying the modules. Often, a first portion of the installation structure underlies a major portion or entirety of a module and a second, inseparable portion comprises packaging for the electronic components of the power conditioning device. Indeed, often both first and second portions may comprise a monolithic material form. In that case the device packaging and electrical components may be designed and incorporated into the installation structure using standardized and automated processing. This feature may significantly reduce the cost of packaging and installation of the conditioning electronics. Moreover, since an individual installation structure may be combined with multiple modules, the costs of power conditioning are spread over an increased magnitude of power. One will also realize that power conditioning at each unit is optional. Alternatively power conditioning may be accomplished by a device receiving power from multiple units. In some applications, no power conditioning may be employed.

Also shown in FIG. 36 are power conveyance conductors 222A and 222B which receive and transport the conditioned power emanating from conditioning device 220. In the embodiment of FIG. 36, the conductors 222 are included as an integral part of the installation structures 214A and 214B. This integral structure is more clearly shown in the FIG. 38 discussed in more detail below. In addition, FIG. 36 also shows integral power return conductors 222C and 222D which transport current at opposite polarity to that conveyed by conductors 222A and 222B. Conductors 222C and 222D may be of similar construction as conductors 222A and 222B. As shown in FIG. 36, the conductors 222 may extend for substantially the full width of the installation unit.

The FIG. 36 embodiment shows two installation units. One will appreciate that various applications may employ one or more units, with the actual number depending on the nature of the photovoltaic elements and the power requirements of the installation. It is understood that structural features taught in the embodiments of FIGS. 18 through 23A may be appropriate in combination with the structural features of the FIG. 36 embodiment.

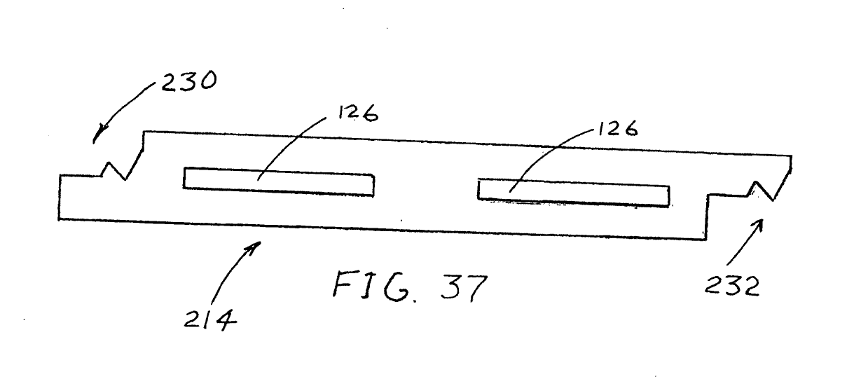

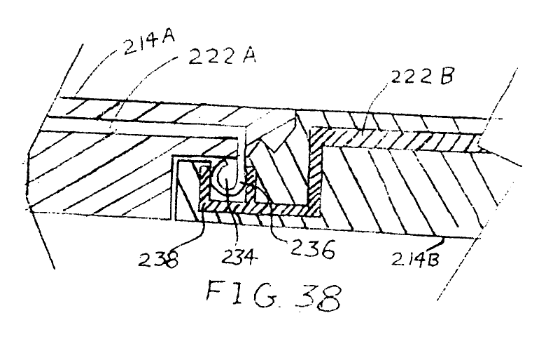

Turning now to FIGS. 37 and 38 there is shown structure allowing multiple units to be both physically and electrically joined. FIG. 37 is a frontal side view of an installation structure 214 such as those of FIG. 36. Note that the photovoltaic modules shown in FIG. 36 are not shown in the FIG. 37 view. The FIG. 37 embodiment comprises “mating” structure at opposite ends. The “mating” structure is generally designated as 230 and 232 in FIG. 37. It is observed that structure 230 at a first side of the installation structure 214 is intended to mate with structure 232 at an opposite side (of a second installation structure) to allow adjacent installation structures to be easily placed in and retain desired relative positioning. Mating structures 230 and 232 can incorporate a wide variety of functional designs. Examples include, but are not limited to, features such as overlapping portions, complimentary forms such as incorporated into structures 230 and 232 illustrated, and interlocking structures such as snap fits. In some embodiments the mating structures may interlock such that multiple structures join together to form an expansive assembly securely locked together to resist destructive effects of weather and the environment.

Also shown in the FIG. 37 embodiment is structure is airspace structure 126. Airspace 126 represents structure intended to accommodate moving equipment such as the forks of a forklift truck or hoisting straps. Thus, the installation structure (and thus the combined installation unit) is able to be moved in a facile manner using, for example, standard forklift procedures.

Turning now to FIG. 38 there is shown a sectional view substantially from the perspective of arrows 38-38 of FIG. 36. FIG. 38 embodies a structure producing electrical interconnection among installation units. In FIG. 38, conductors 222A carrying the output power from a first unit is transported to an adjacent unit conductor 222B at electrical connection 234. In the FIG. 38, the electrical connection is represented by a compression fitting connecting the two conductors. A “male” extension 236 of conductor 222A has the form of a collapsible “spiral”. A “female” receptacle 238 of conductor 222B is positioned to receive extension 236. When the two installation units are positioned adjacent each other, extension 236 is simultaneously inserted into receptacle 238. Receptacle 238 is sized to slightly compress the spiral structure of extension 236 such that insertion results in electrical contact between conductors 222A and 222B. One of skill in the art will realize that the compression connection structure depicted in FIG. 38 is only one of many possible ways to achieve electrical connection between the two conductors 222A and 222B. Other conductive joining techniques, such as mechanical connectors, conductive adhesives and solders, and conductive bridging straps may be chosen to accomplish the electrical connection.

In the embodiments of FIG. 36-38, the conductors 222 are indicated as integral to the installation structure and embedded or otherwise shielded from exterior exposure. This includes extension 236 when inserted into receptacle 238. Thus, high voltages may be generated by the corresponding power conditioning devices 220 without a need for excessive additional electrical insulation to protect against high voltage exposure.

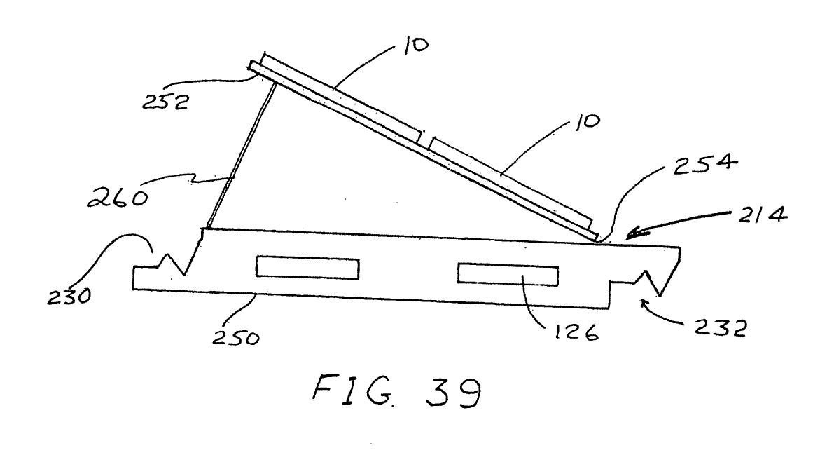

Referring now to FIG. 39, there is seen a side view of another embodiment of an installation unit comprising photovoltaic modules 10 combined with installation structure 214. In the FIG. 39 embodiment, hinge 254 joins a first portion of installation structure 250 and a second portion of installation structure 252. In the embodiment pole 260 maintains second portion 252 at an angle to the horizontal as shown. One will appreciate that other versions of installation structure such as those illustrated in FIGS. 18 through 23A and FIGS. 36 through 38 could incorporate similar multi-portion structures connected through hinges to allow relative movement. The modules may be attached to the first portion to thereby enable tilting of the modules relative to a second stationary portion of the installation structure. In this way the units could be stacked substantially “flat” for manufacture, storage and shipment yet the modules could be tilted in use according to season and latitude. One can appreciate that the mass production possibility of the installation units would enable inexpensive hinge designs such as polymeric integral living hinges or snap hinges.

Although the present invention has been described in conjunction with preferred embodiments, it is to be understood that modifications, alternatives and equivalents may be included without departing from the spirit and scope of the inventions, as those skilled in the art will readily understand. Such modifications, alternatives and equivalents are considered to be within the purview and scope of the invention and appended claims.

What is claimed:

1. A photovoltaic installation unit comprising, in combination,
one or more photovoltaic modules, said photovoltaic modules comprising one or more electrically interconnected photovoltaic cells,
installation structure, said installation structure comprising a first portion with an upwardly facing expanse underlying a major portion of a first of said one or more photovoltaic modules, and a second portion comprising packaging for power conditioning electronics,
and wherein said first and second portions are integral and inseparable.

2. The photovoltaic installation unit of claim 1 wherein said first and second portions comprise a common monolithic material form.

3. The photovoltaic installation unit of claim 1 wherein said power conditioning device is designed to increase the voltage produced by said one or more electrically connected photovoltaic cells.

4. The photovoltaic installation unit of claim 1 comprising multiple photovoltaic modules and wherein said upwardly facing expanse underlies a second of said multiple modules.

5. The photovoltaic installation unit of claim 1 wherein said upwardly facing expanse is formed by plastic.

6. The photovoltaic installation unit of claim 1 further comprising structure designed to accommodate ballast material.

7. The photovoltaic installation unit of claim 6 wherein said ballast material is a liquid.

8. A photovoltaic installation unit comprising, in combination,
one or more photovoltaic modules, said photovoltaic modules comprising one or more electrically interconnected photovoltaic cells,
installation structure, said installation structure comprising a first portion with an upwardly facing expanse underlying a first of said one or more photovoltaic modules, and a second portion comprising a first electrical conductor electrically connected to receive photovoltaically generated current of a first polarity from said first of said one or more photovoltaic modules,
and wherein said first and second portions are integral and inseparable.

9. The installation unit of claim 8 wherein,
said installation unit of claim 8 is the first of multiple installation units and the said installation structure of said first unit further comprises a first electrical connector,
said first electrical connector of said first unit is complimentary to a second electrical connector on the installation structure of a second of said multiple units,
such that when the said first and second installation units are positioned adjacent each other the first and second electrical connectors engage to allow passage of current between said first and second units.

10. The photovoltaic installation unit of claim 8 wherein said installation structure comprises a third portion comprising an electrical conductor electrically connected to convey current of polarity opposite said first polarity, and wherein said third portion is integrally incorporated into said installation structure such that said first, second and third portions are inseparable.

11. The photovoltaic installation unit of claim 8 wherein a first of said one or more photovoltaic modules comprises a collection surface greater than 2 square feet.

12. A photovoltaic installation unit comprising, in combination,
one or more photovoltaic modules, said photovoltaic modules comprising one or more electrically interconnected photovoltaic cells,
installation structure designed and constructed to be included in a permanent, stationary photovoltaic power collection installation and comprising an upward facing expanse onto which said one or more photovoltaic modules are mounted,
wherein said installation structure additionally is designed to permit facile movement of said unit.

13. The photovoltaic installation unit of claim 12 wherein,
said installation unit is the first of multiple installation units and the installation structure of said first installation unit comprises a first mating structure,
said first mating structure of said first installation unit is complimentary to second mating structure on the installation structure of a second of said multiple installation units,
such that said first and second mating structures on said first and second installation structures of said first and second installation units respectively interact to establish and maintain relative positioning of said first and second units when they are placed adjacent to one another.

14. The photovoltaic installation unit of claim 12 wherein said installation structure includes structure suitable for receiving the forks of a forklift device or hoisting straps to thereby permit said facile movement of said unit.

15. The photovoltaic installation unit of claim 12 wherein said photovoltaic installation unit of claim 12 is the first of multiple installation units and is positioned adjacent a second installation unit, and wherein an elongate rail extends between said first and second units and is affixed to said first and second units such that said first and second units are maintained in relative position.

16. The photovoltaic installation unit of claim 15 wherein said rail comprises a metal.

17. The photovoltaic installation of claim 15 wherein said rail also is intended to conduct photovoltaically generated power.

18. The photovoltaic installation unit of claim 12 further comprising structure designed to accommodate ballast material.

19. The photovoltaic installation unit of claim 18 wherein said structure designed to accommodate ballast material comprises a tank to hold liquid.

20. The photovoltaic installation unit of claim 19 wherein said tank is blow molded and constructed of plastic material.
